(19) United States
(12) Patent Application Publication
(10) Pub. No.: US 2025/0287786 A1
(43) Pub. Date: Sep. 11, 2025

(54) DISPLAY PANEL AND MANUFACTURING METHOD OF THE SAME

(71) Applicant: Samsung Display Co., Ltd., Yongin-si (KR)

(72) Inventors: SEON UK LEE, Yongin-si (KR); DONGHYEON KI, Yongin-si (KR); KWANG-HYUN KIM, Yongin-si (KR); KEUNCHAN OH, Yongin-si (KR); SEONGYOUNG LEE, Yongin-si (KR); SUN-KYU JOO, Yongin-si (KR); SEOK-JOON HONG, Yongin-si (KR); TAE HYUNG HWANG, Yongin-si (KR)

(73) Assignee: Samsung Display Co., Ltd., Yongin-si (KR)

(21) Appl. No.: 19/052,864

(22) Filed: Feb. 13, 2025

(30) Foreign Application Priority Data
Mar. 8, 2024 (KR) 10-2024-0032991

(51) Int. Cl. H10K 59/122; H10K 59/38

(52) U.S. Cl. CPC H10K 59/122; H10K 59/38

(57) ABSTRACT

A display panel includes a display element layer including a light-emitting element that outputs a source light and an optical structure layer on the light-emitting element and transmitting or converting the source light into light of a different wavelength. The optical structure layer includes a bank on the light-emitting element and having a first to third bank openings and a light control layer including a first to third light control patterns in the first to third bank openings. A first bank region defined by the first bank opening includes a first sub-region and a second sub-region protruding from the first sub-region in the first direction. A second bank region defined by the second bank opening includes a third sub-region and a fourth sub-region protruding from the third sub-region in a direction opposite to the first direction.

### CROSS-REFERENCE TO RELATED APPLICATION(S)

This application claims priority to and benefits of Korean Patent Application No. 10-2024-0032991 under 35 U.S.C. § 119, filed on Mar. 8, 2024, in the Korean Intellectual Property Office (KIPO). the entire contents of which are incorporated herein by reference.

### BACKGROUND

### 1. Technical Field

The disclosure herein relates to a display panel and a method of manufacturing the same having improved manufacturing process efficiency and display quality while increasing resolution.

### 2. Description of Related Art

A display panel includes a transmissive display panel that selectively transmits source light generated from a light source and a light-emitting display panel that generates source light in the display panel itself. The display panel may include different types of light control patterns according to pixels in order to generate a color image. The light control pattern may transmit only certain wavelength ranges of the source light or transform the color of the source light. Some light control patterns may change the characteristics of light without changing the color of the source light.

### SUMMARY

The disclosure provides a display panel capable of implementing high resolution and having improved display quality.

The disclosure also provides a method of manufacturing a display panel having improved manufacturing process efficiency.

According to an embodiment of the disclosure, a display panel may include a display element layer including a light-emitting element that outputs a source light, and an optical structure layer that is disposed on the light-emitting element and transmits the source light or converts the source light into light of a different wavelength. The optical structure layer may include a light control layer disposed on the light-emitting element and including a bank having a first bank opening, a second bank opening, and a third bank opening sequentially disposed in a first direction, a first light control pattern disposed in the first bank opening, a second light control pattern disposed in the second bank opening, and a third light control pattern disposed in the third bank opening. A first bank region defined by the first bank opening may include a first sub-region extending in a second direction intersecting the first direction and a second sub-region protruding from the first sub-region in the first direction. A second bank region defined by the second bank opening may include a third sub-region extending in the second direction, and a fourth sub-region protruding from the third sub-region in a direction opposite to the first direction to the first bank region. A third bank region may be defined by the third bank opening. Center lines of the second sub-region and the fourth sub-region in the second direction may not overlap each other in the first direction. Center lines of the first sub-region, the third sub-region, and the third bank region in the second direction may be aligned with each other.

In an embodiment, each of the second sub-region and the fourth sub-region may include a hypotenuse extending in a diagonal direction forming an acute angle with the first direction.

In an embodiment, a length of the third bank region in the second direction may be less than a length of each of the first bank region and the second bank region in the second direction.

In an embodiment, the first sub-region may include a first side and a second side each extending in the first direction and spaced apart from each other in the second direction, and the third sub-region may include a third side and a fourth side each extending in the first direction and spaced apart from each other in the second direction. The first side and the third side may be aligned with each other in the first direction, and the second side and the fourth side may be aligned with each other in the first direction.

In an embodiment, the second sub-region may include a fifth side aligned with the second side in the first direction, and the fourth sub-region may include a sixth side aligned with the third side in the first direction.

In an embodiment, the optical structure layer may further include a color filter layer disposed on the light control layer. The color filter layer may include a first color filter overlapping the first bank region in a plan view, a second color filter overlapping the second bank region in a plan view, and a third color filter overlapping the third bank region in a plan view.

In an embodiment, the first color filter may be disposed in a first filter region that emits light of a first wavelength, the second color filter may be disposed in a second filter region that emits light of a second wavelength, and the third color filter may be disposed in a third filter region that emits light of a third wavelength. The third wavelength may be shorter than the first wavelength and the second wavelength.

In an embodiment, the third filter region may have a rectangular shape in a plan view.

In an embodiment, the first filter region may include a first sub-filter region overlapping the first sub-region in a plan view and a second sub-filter region protruding from the first sub-filter region in the first direction and at least partially overlapping the second sub-region in a plan view. The second filter region may include a third sub-filter region overlapping the third sub-region in a plan view and a fourth sub-filter region protruding from the third sub-filter region in a direction opposite to the first direction and at least partially overlapping the fourth sub-region in a plan view.

In an embodiment, a minimum distance from an end of the first sub-region to an end of the first filter region and a minimum distance from an end of the second sub-region to an end of the second filter region may be substantially equal.

In an embodiment, the second bank region may further include a fifth sub-region protruding from the third sub-region in the first direction to the third bank region. The third bank region may include a sixth sub-region extending in the second direction and a seventh sub-region protruding from the sixth sub-region in a direction opposite to the first direction to the second bank region.

In an embodiment, a length of the second sub-region and a length of the fourth sub-region in the second direction may be substantially same.

In an embodiment, a length of the second sub-region and a length of the fourth sub-region may be different from each other in the second direction.

In an embodiment, the third bank region may have a rectangular shape in a plan view.

In an embodiment, the third light control pattern may include a photosensitive resin.

In an embodiment, a width of the first sub-region and a width of the third sub-region in the first direction may be substantially same.

In an embodiment, a separation distance from the second sub-region to the third sub-region and separation distance from the third sub-region to the third bank region in the first direction may be substantially same.

In an embodiment of the disclosure, a display panel may include a display element layer including a light-emitting element that outputs a source light, and an optical structure layer that is disposed on the light-emitting element and transmits the source light or converts the source light into light of a different wavelength. The optical structure layer may include a light control layer disposed on the light-emitting element and including a bank having a first bank opening, a second bank opening, and a third bank opening sequentially disposed in a first direction, a first light control pattern disposed in the first bank opening, a second light control pattern disposed in the second bank opening, and a third light control pattern disposed in the third bank opening. A first bank region defined by the first bank opening may include a first sub-region and a second sub-region protruding from the first sub-region in the first direction. A second bank region defined by the second bank opening may include a third sub-region and a fourth sub-region protruding from the third sub-region in a direction opposite to the first direction to the first bank region. A third bank region may be defined by the third bank opening. Each of the second sub-region and the fourth sub-region may protrude in a staggered form from an upper portion or a lower portion of a side of each of the first sub-region and the third sub-region. Center lines of the first sub-region, the third sub-region, and the third bank region in a second direction intersecting the first direction may be aligned with each other.

In an embodiment, each of the second sub-region and the fourth sub-region may include a hypotenuse extending in a diagonal direction which is a direction between the first direction and the second direction.

In an embodiment of the disclosure, a method of manufacturing a display panel may include preparing a display element layer including a light-emitting element that outputs a source light and forming an optical structure layer on the light-emitting element. The forming of the optical structure layer may include forming a bank including a first bank opening, a second bank opening, and a third bank opening sequentially formed in a first direction, on the light-emitting element, patterning a photoresist material in the third bank opening to form a third light control pattern, and forming a first light control pattern in the first bank opening and a second light control pattern in the second bank opening through an inkjet process. A first bank region defined by the first bank opening may include a first sub-region extending in a second direction intersecting the first direction, and a second sub-region protruding from the first sub-region in the first direction. A second bank region defined by the second bank opening may include a third sub-region extending in the second direction and a fourth sub-region protruding from the third sub-region in a direction opposite to the first direction to the first bank region. A third bank region may be defined by the third bank opening. Center lines of the second sub-region and the fourth sub-region in the second direction may not overlap each other in the first direction, and center lines of the first sub-region, the third sub-region, and the third bank region in the second direction may be aligned with each other.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain principles of the disclosure. In the drawings:

FIG. 1A is a block diagram of an electronic device according to an embodiment of the disclosure.

FIG. 1B is a perspective view of a display panel according to an embodiment of the disclosure;

FIG. 1C is a schematic cross-sectional view of the display panel according to an embodiment of the disclosure;

FIG. 1D is a plan view of the display panel according to an embodiment of the disclosure;

FIG. 2 is an enlarged plan view of a portion of the display panel according to an embodiment of the disclosure;

FIG. 3 is a schematic cross-sectional view of a portion of the display panel according to an embodiment of the disclosure;

FIGS. 4A, 4B, 4C, and 4D are each a schematic cross-sectional view of a portion of a display panel according to an embodiment of the disclosure;

FIG. 5 is a schematic cross-sectional view of a light-emitting element according to an embodiment of the disclosure;

FIG. 6A is an enlarged plan view of a portion of a display panel according to an embodiment of the disclosure;

FIG. 6B is an enlarged plan view of some of the components of the display panel according to an embodiment of the disclosure;

FIGS. 7A, 7B, 7C, 7D, 7E, and 7E are each an enlarged plan view of a portion of a display panel according to an embodiment of the disclosure;

FIG. 8A is a flowchart of a method of manufacturing a display panel according to an embodiment of the disclosure;

FIG. 8B is a flowchart of some steps in the method of manufacturing the display panel according to an embodiment of the disclosure; and

FIGS. 9A, 9B, 9C, and 9D are schematic cross-sectional views illustrating some steps in the method of manufacturing the display panel according to an embodiment of the disclosure.

### DETAILED DESCRIPTION OF THE EMBODIMENTS

Hereinafter, embodiments of the disclosure will be described with reference to the drawings.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

Like reference numerals refer to like elements throughout. In addition, in the drawings, the thicknesses, ratios, and dimensions of elements are exaggerated for effective description of the technical contents. As used herein, the term “and/or” includes any and all combinations that the associated configurations can define.

It will be understood that, although the terms first, second, etc. may be used herein to describe various elements, these elements should not be limited by these terms. These terms are only used to distinguish one element from another element. For example, a first element could be termed a second element without departing from the scope of the disclosure. Similarly, the second element may also be referred to as the first element. The terms of a singular form include plural forms unless otherwise specified.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

It will be understood that the terms “include” and/or “have”, when used in this specification, specify the presence of stated features, integers, steps, operations, elements, components and/or groups thereof, but do not preclude the presence or addition of one or more other features, integers, steps, operations, elements, components, and/or groups thereof.

In the application, being “directly disposed” may mean that there is no layer, film, region, plate, or the like added between a part such as a layer, film, region, or plate and another part such as a layer, film, region, or plate. For example, being “directly disposed” may mean that no additional member such as an adhesive member is disposed between two layers or two members.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, a display panel and a method of manufacturing the display panel according to an embodiment of the disclosure will be described with reference to the accompanying drawings.

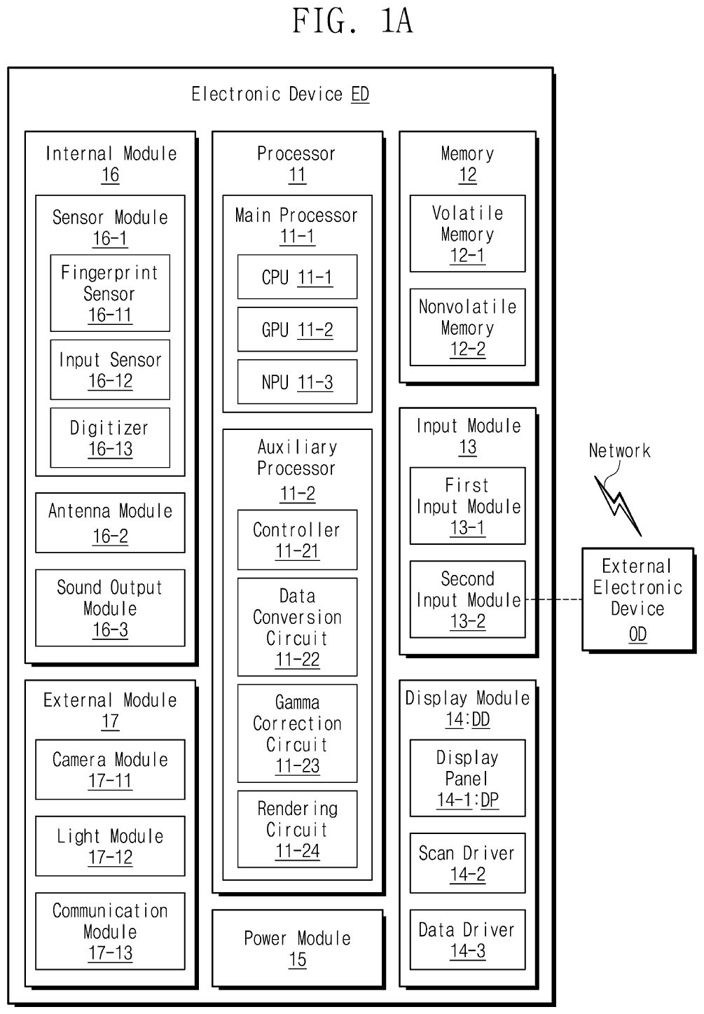

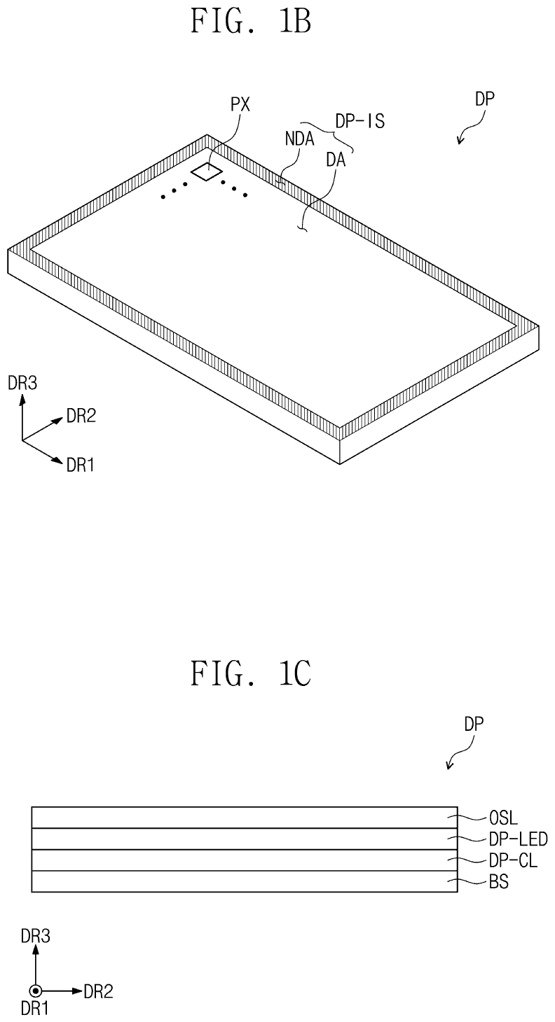

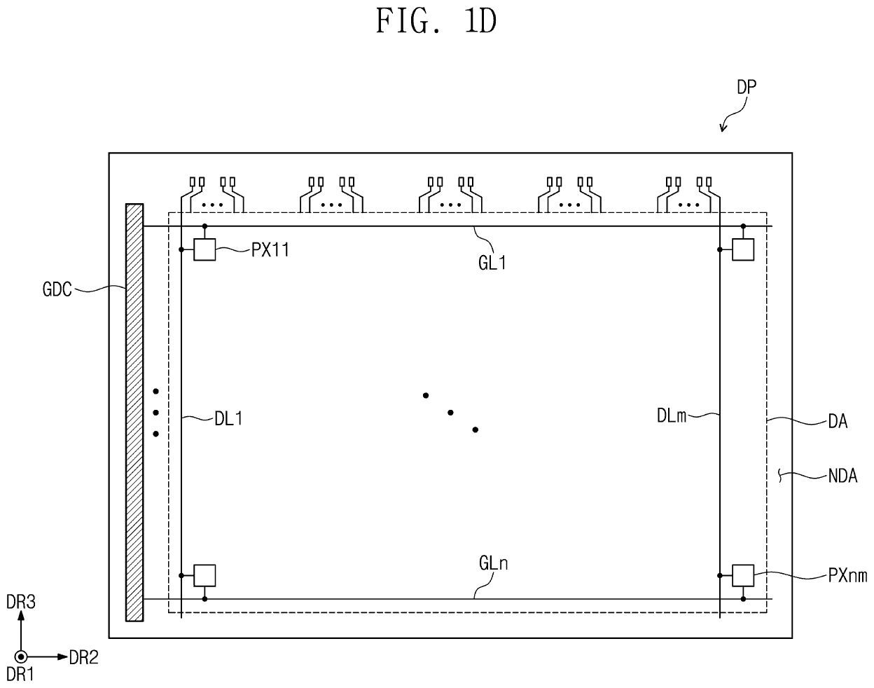

FIG. 1A is a block diagram of an electronic device according to an embodiment of the disclosure.

Referring to FIG. 1A, an electronic device ED outputs various information through a display module 14 in an operating system. When a processor 11 executes an application stored in a memory 12, the display module 14 provides application information to a user through a display panel 14-1. Meanwhile, the display panel 14-1 may refer to the display panel DP (see FIG. 1B).

The processor 11 obtains an external input through an input module 13 or a sensor module 16-1 and executes an application corresponding to the external input. For example, when a user selects a camera icon displayed on the display panel 14-1, the processor 11 obtains a user's input through an input sensor 16-12 and activates a camera module 17-1. The processor 11 transmits, to the display module 14, image data corresponding to a captured image that is obtained through the camera module 17-1. The display module 14 may display an image corresponding to the captured image through the display panel 14-1.

For another example, when personal information authentication is executed in the display module 14, a fingerprint sensor 16-11 obtains input fingerprint information as input data. The processor 11 compares the input data obtained through the fingerprint sensor 16-11 with authentication data stored in the memory 12 and executes an application according to a comparison result. The display module 14 may display information that is executed according to a logic of the application through the display panel 14-1.

For another example, when a music streaming icon displayed through the display module 14 is selected, the processor 11 obtains a user input through the input sensor 16-12 and activates a music streaming application stored in the memory 12. When a music execution command is input in the music streaming application, the processor 11 activates a sound output module 16-3 and provides sound information corresponding to the music execution command to a user.

An operation of the electronic device ED is briefly described above. Hereinafter, a configuration of the electronic device ED will be described in detail. Some of components of the electronic device ED to be described later may be integrated and provided as one component, and one component may be separated and provided as two or more components.

the electronic device ED may communicate with an external electronic device OD through a network (for example, short-range wireless communication network or long-range wireless communication network). According to an embodiment, the electronic device ED may include the processor 11, the memory 12, the input module 13, the display module 14, a power module 15, an internal module 16, and an external module 17. According to an embodiment, in the electronic device ED, at least one of the components described above may be omitted, or one or more other components may be added. According to an embodiment, some (for example, the sensor module 16-1, an antenna module 16-2, or the sound output module 16-3) of the components described above may be integrated to another component (for example, the display module 14).

The processor 11 may execute software to control at least one other component (for example, hardware or software component) of the electronic device ED connected to the processor 11 and perform various data processing or operations. According to an embodiment, as at least part of the data processing or operations, the processor 11 may store data or a command received from another component (for example, the input module 13, the sensor module 16-1, or a communication module 17-3) in a volatile memory 12-1 and process the data or command stored in the volatile memory 12-1, and result data may be stored in a nonvolatile memory 12-2.

The processor 11 may include a main processor 11-1 and an auxiliary processor 11-2. The main processor 11-1 may include one or more among a central processing unit (CPU) 11-11 and an application processor (AP). The main processor 11-1 may further include one or more among a graphic processing unit (GPU) 11-12, a communication processor (CP), and an image signal processor (ISP). The main processor 11-1 may further include a neural processing unit (NPU) 11-13. A neural processing unit is a processor that is specialized for processing an artificial intelligence model, and the artificial intelligence model may be generated through machine learning. The artificial intelligence model may include a plurality of artificial neural network layers. An artificial neural network may be one of a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-networks, and a combination of two or more thereof, but is not limited to the examples described above. The artificial intelligence model may include software structure in addition to or instead of hardware structure. At least two among the processing units and processors described above may be implemented as one integrated component (for example, a single chip) or may be each implemented as an independent component (for example, a plurality of chips).

The auxiliary processor 11-2 may include a controller 11-21. The controller 11-21 may include an interface conversion circuit and a timing control circuit. The controller 11-21 receives an image signal from the main processor 11-1, converts data format of the image signal to comply with specifications of interface with the display module 14, and outputs image data. The controller 11-21 may output various control signals required for driving the display module 14.

The auxiliary processor 11-2 may further include a data conversion circuit 11-22, a gamma correction circuit 11-23, a rendering circuit 11-24, etc. The data conversion circuit 11-22 may receive image data from the controller 11-21, and may compensate for the image data such that an image is displayed at a desired luminance according to characteristics of the electronic device ED, a user's setting, or the like, or may convert the image data to reduce power consumption, to compensate for an afterimage, or the like. The gamma correction circuit 11-23 may convert image data, a gamma reference voltage, or the like such that an image displayed on the electronic device ED has a desired gamma characteristic. The rendering circuit 11-24 may receive image data from the controller 11-21 and render the image data in consideration of pixel arrangement of the display panel 14-1 applied to the electronic device ED, etc. At least one of the data conversion circuit 11-22, the gamma correction circuit 11-23, or the rendering circuit 11-24 may be integrated to another component (for example, the main processor 11-1 or the controller 11-21). At least one of the data conversion circuit 11-22, the gamma correction circuit 11-23, or the rendering circuit 11-24 may be integrated to a data driver 143 to be described later.

The memory 12 may store various pieces of data that are used by at least one component (for example, the processor 11 or the sensor module 16-1) of the electronic device ED, and output data or input data about a command related thereto. The memory 12 may include at least one of the volatile memory 12-1 or the nonvolatile memory 12-2.

The input module 13 may receive data or a command to be used for a component (for example, the processor 11, the sensor module 16-1, or the sound output module 16-3) of the electronic device ED from the outside (for example, a user or the external electronic device OD) of the electronic device ED.

The input module 13 may include a first input module 13-1 to which a command or data is input from a user and a second input module 13-2 to which a command or data is input from the external electronic device OD. The first input module 13-1 may include a microphone, a mouse, a keyboard, a key (for example, a button), or a pen (for example, a passive pen or an active pen). The second input module 13-2 may support a designated protocol for connection to the external electronic device OD wirelessly or by wire. According to an embodiment, the second input module 13-2 may include a high definition multimedia interface (HDMI), a universal serial bus (USB) interface, an SD card interface, or an audio interface. The second input module 13-2 may include a connector, for example, an HDMI connector, a USB connector, an SD card connector, or an audio connector (for example, a headphone connector), for physical connection to the external electronic device OD.

The display module 14 visually provides information to a user. The display module 14 may include the display panel 14-1, a scan driver 14-2, and the data driver 143. The display module 14 may further include a chassis and a bracket for protecting the display panel 14-1.

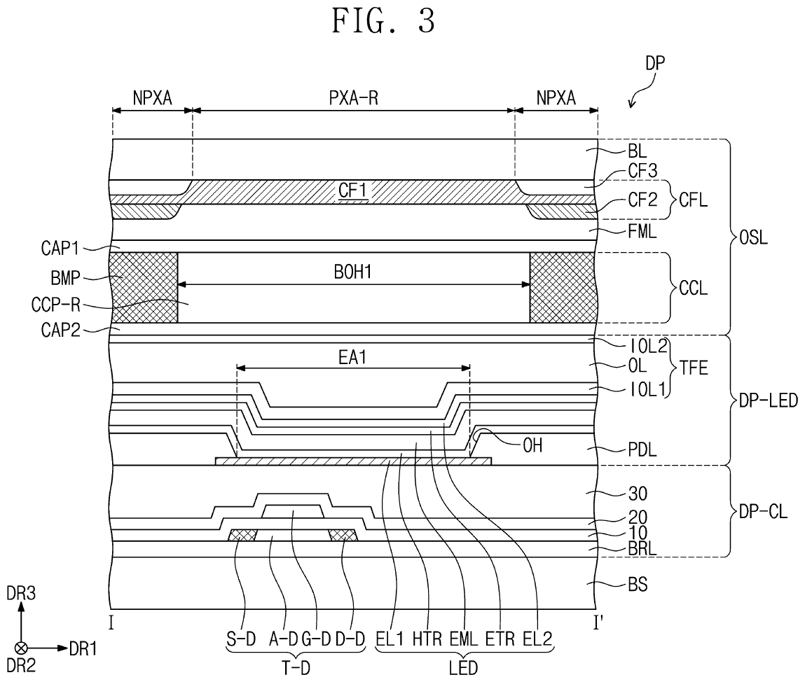

The display panel 14-1 may include a liquid crystal display panel, an organic light-emitting display panel, or an inorganic light-emitting display panel, and a type of the display panel 14-1 is not particularly limited. The display panel 14-1 may be a rigid-type or flexible-type panel capable of being rolled or folded. The display module 14 may further include a supporter that supports the display panel 14-1, a bracket, a heat dissipation member, or the like. The display panel 14-1 will be described in detail below with reference to FIG. 3 and subsequent drawings.

The scan driver 14-2 may be mounted on the display panel 14-1 as a driving chip. In addition, the scan driver 14-2 may be integrated to the display panel 14-1. For example, the scan driver 14-2 may include an amorphous silicon TFT gate driver circuit (ASG), a low temperature polycrystalline silicon (LTPS) TFT gate driver circuit, or an oxide semiconductor TFT gate driver circuit (OSG) built in the display panel 14-1. The scan driver 14-2 receives a control signal from the controller 11-21 and outputs scan signals to the display panel 14-1 in response to the control signal.

The display panel 14-1 may further include a light emission driver. The light emission driver outputs a light emission control signal to the display panel 14-1 in response to a control signal received from the controller 11-21. The light emission driver may be formed separately from the scan driver 14-2 or may be integrated to the scan driver 14-2.

The data driver 143 receives a control signal from the controller 11-21, converts image data into an analog voltage (for example, a data voltage) in response to the control signal, and then outputs data voltages to the display panel 14-1.

The data driver 143 may be integrated to another component (for example, the controller 11-21). Functions of the interface conversion circuit and the timing control circuit of the controller 11-21 described above may be integrated to the data driver 143.

The display module 14 may further include a light emission driver, a voltage generation circuit, and the like. The voltage generation circuit may output various voltages required for driving the display panel 14-1.

The power module 15 supplies power to a component of the electronic device ED. The power module 15 may include a battery that charges a power voltage. The battery may include a non-rechargeable primary cell, a rechargeable secondary cell, or a fuel cell. The power module 15 may include a power management integrated circuit (PMIC). The PMIC supplies optimized power to each of the module described above and a module to be described later. The power module 15 may include a wireless power transmission/reception member electrically connected to the battery. The wireless power transmission/reception member may include a plurality of antenna radiators in a coil form.

The electronic device ED may further include the internal module 16 and the external module 17. The internal module 16 may include the sensor module 16-1, the antenna module 16-2, and the sound output module 16-3. The external module 17 may include the camera module 17-1, a light module 17-2, and the communication module 17-3.

The sensor module 16-1 may sense an input from a user's body or an input from a pen of the first input module 13-1 and generate a data value or an electrical signal corresponding to the input. The sensor module 16-1 may include at least one of the fingerprint sensor 16-11, the input sensor 16-12, or a digitizer 16-13.

The fingerprint sensor 16-11 may generate a data value corresponding to a user's fingerprint. The fingerprint sensor 16-11 may include any one of an optical fingerprint sensor and a capacitive fingerprint sensor.

The input sensor 16-12 may generate a data value corresponding to coordinate information about an input from a user's body or an input from a pen. The input sensor 16-12 generates the amount of a change in capacitance due to an input as a data value. The input sensor 16-12 may sense an input from a passive pen or transmit/receive data to/from an active pen.

The input sensor 16-12 may measure a biosignal such as blood pressure, water, or body fat. For example, when a user is in contact with a sensor layer or a sensing panel with a part of the user's body and does not move for a certain amount of time, the input sensor 16-12 may sense a biosignal on the basis of a change in electric field due to the part of the user's body and output information desired by the user to the display module 14.

The digitizer 16-13 may generate a data value corresponding to coordinate information about an input from a pen. The digitizer 16-13 generates the amount of an electromagnetic change due to an input as a data value. The digitizer 16-13 may sense an input from a passive pen or transmit/receive data to/from an active pen.

At least one of the fingerprint sensor 16-11, the input sensor 16-12, or the digitizer 16-13 may be implemented as an input sensing layer ISL (see FIG. 3) that is formed on the display panel 14-1 through a continuous process. The fingerprint sensor 16-11, the input sensor 16-12, and the digitizer 16-13 may be disposed above the display panel 14-1, and any one of the fingerprint sensor 16-11, the input sensor 16-12, and the digitizer 16-13, for example, the digitizer 16-13 may be disposed below the display panel 14-1.

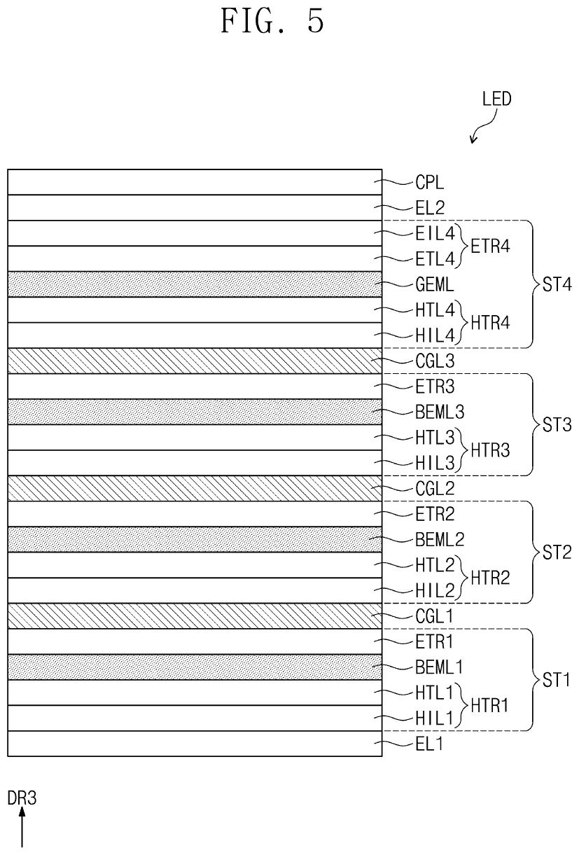

At least two of the fingerprint sensor 16-11, the input sensor 16-12, and the digitizer 16-13 may be formed to be integrated as one sensing panel through the same process. In a case in which the at least two thereof are integrated to one sensing panel, the sensing panel may be disposed between the display panel 14-1 and the window module WM (see FIG. 3) disposed above the display panel 14-1. According to an embodiment, the sensing panel may be disposed on the window module WM (see FIG. 3), and a position of the sensing panel is not particularly limited. FIG. 5 to be described later illustrates an input sensing part ISP disposed between the display panel 14-1 and the window module WM (see FIG. 3) disposed above the display panel 14-1, but an embodiment is not limited thereto.

At least one of the fingerprint sensor 16-11, the input sensor 16-12, or the digitizer 16-13 may be built in the display panel 14-1. That is, at least one of the fingerprint sensor 16-11, the input sensor 16-12, or the digitizer 16-13 may be simultaneously formed through a process of forming elements (for example, a light-emitting element, a transistor, etc.) included in the display panel 14-1.

In addition, the sensor module 16-1 may generate a data value or an electrical signal corresponding to an internal state or an external state of the electronic device ED. The sensor module 16-1 may further include, for example, a gesture sensor, a gyro sensor, a barometric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The antenna module 16-2 may include one or more antennas for transmitting or receiving a signal or power to or from the outside. According to an embodiment, the communication module 17-3 may transmit or receive a signal to or from an external electronic device through an antenna suitable for a communication method. An antenna pattern of the antenna module 16-2 may be integrated to one component (for example, the display panel 14-1) of the display module 14, the input sensor 16-12, or the like.

The sound output module 16-3 may be a device for outputting a sound signal to the outside of the electronic device ED and include, for example, a speaker that is used for general purposes such as playing multimedia or playing a recording and a receiver that is used only for receiving a call. According to an embodiment, the receiver may be formed integrally with or separately from the speaker. A sound output pattern of the sound output module 16-3 may be integrated to the display module 14.

The camera module 17-1 may capture a still image and a moving image. According to an embodiment, the camera module 17-1 may include one or more lenses, an image sensor, or an image signal processor. The camera module 17-1 may further include an infrared camera capable of measuring presence/absence of a user, a position of a user, a gaze of a user, etc.

The light module 17-2 may provide light. The light module 17-2 may include a light-emitting diode or a xenon lamp. The light module 17-2 may operate in association with the camera module 17-1 or may operate independently.

The communication module 17-3 may support establishing a wired or wireless communication channel between the electronic device ED and the external electronic device OD and performing communication via the established communication channel. The communication module 17-3 may include any one of or both of a wireless communication module such as a cellular communication module, a short-range wireless communication module, or a global navigation satellite system (GNSS) communication module and a wired communication module such as a local area network (LAN) communication module or a power line communication module. The communication module 17-3 may communicate with the external electronic device OD via a short-range communication network such as Bluetooth, Wi-Fi direct, or infrared data association (IrDA) or a long-range communication network such as a cellular network, internet, or a computer network (for example, LAN or WAN). The various types of the communication module 17-3 described above may be implemented as one chip or may be implemented as separate chips.

The input module 13, the sensor module 16-1, the camera module 17-1, etc., may be used to control an operation of the display module 14 in association with the processor 11.

The processor 11 outputs a command or data to the display module 14, the sound output module 16-3, the camera module 17-1, or the light module 17-2 on the basis of input data received from the input module 13. For example, the processor 11 may generate image data in correspondence to input data applied through a mouse, an active pen, or the like and output the image data to the display module 14, or may generate command data in correspondence to input data and output the command data to the camera module 17-1 or the light module 17-2. When input data is not received from the input module 13 for a certain amount of time, the processor 11 may change an operation mode of the electronic device ED to a low power mode or a sleep mode, thereby reducing power consumption of the electronic device ED.

The processor 11 outputs a command or data to the display module 14, the sound output module 16-3, the camera module 17-1, or the light module 17-2 on the basis of sensing data received from the sensor module 16-1. For example, the processor 11 may compare authentication data applied by the fingerprint sensor 16-11 with authentication data stored in the memory 12, and then may execute an application according to a comparison result. The processor 11 may execute a command or output corresponding image data to the display module 14 on the basis of sensing data sensed by the input sensor 16-12 or the digitizer 16-13. In a case in which a temperature sensor is included in the sensor module 16-1, the processor 11 may receive temperature data about a measured temperature from the sensor module 16-1 and further perform luminance correction on image data, etc., on the basis of the temperature data.

The processor 11 may receive measurement data about presence/absence of a user, a position of a user, a gaze of a user, etc., from the camera module 17-1. The processor 11 may further perform luminance correction on image data, etc., on the basis of the measurement data. For example, the processor 11 determines presence/absence of a user through an input from the camera module 17-1, and then the processor 11 may output image data of which luminance is corrected through the data conversion circuit 11-22 or the gamma correction circuit 11-23 to the display module 14.

Some of the above components may be connected to each other via a communication method between peripheral devices, for example, bus, general purpose input/output (GPIO), serial peripheral interface (SPI), mobile industry processor interface (MIPI), or ultra path interconnect (UPI) link, and may exchange a signal (for example, a command or data). The processor 11 may communicate with the display module 14 via a mutually agreed interface, and for example, may use one of the communication methods described above, and a communication method is not limited thereto.

FIG. 1B is a perspective view of a display panel according to an embodiment of the disclosure. FIG. 1C is a schematic cross-sectional view of the display panel according to an embodiment of the disclosure. FIG. 1D is a plan view of the display panel according to an embodiment of the disclosure.

As illustrated in FIG. 1B, the display panel DP may display an image through a display surface DP-IS. The display surface DP-IS may be parallel to a plane defined by a first direction DR1 and a second direction DR2. The display surface DP-IS may include a display region DA and a non-display region NDA. A pixel PX may be disposed in the display region DA, and a pixel PX may not be disposed in the non-display region NDA. The non-display region NDA may be defined along the border of the display surface DP-IS. The non-display region NDA may surround the display region DA in a plan view. Without being limited thereto, however, in another embodiment of the disclosure, the non-display region NDA may be omitted or disposed only on a side of the display region DA.

The normal direction of the display surface DP-IS, for example, the thickness direction of the display panel DP may be indicated by a third direction DR3. The front (or upper) and rear (or lower) surfaces of each layer or unit described below may be divided by the third direction DR3. However, the first to third directions DR1, DR2, and DR3 is not limited thereto.

Although the display panel DP having a flat display surface DP-IS is illustrated in FIG. 1B, the disclosure is not limited thereto. The display panel DP may include a curved display surface or a three-dimensional display surface. The three-dimensional display surface may include multiple display regions facing different directions.

As illustrated in FIG. 1C, the display panel DP may include a base substrate BS, a circuit element layer DP-CL, a display element layer DP-LED, and an optical structure layer OSL. The base substrate BS may be a synthetic resin substrate or a glass substrate. The circuit element layer DP-CL may include at least one insulating layer and a circuit element. The circuit element may include a signal line, a pixel driving circuit, and the like. The circuit element layer DP-CL may be formed through a process of forming an insulating layer, a semiconductor layer, and a conductive layer by coating, deposition, etc., and through a process of patterning the insulating layer, the semiconductor layer, and the conductive layer by a photolithography method. The display element layer DP-LED may include at least one display element. The optical structure layer OSL may convert the color of light provided from the display element. The optical structure layer OSL may include a light control pattern and a structure to increase light conversion efficiency.

FIG. 1D schematically illustrates the planar arrangement relationship of signal lines GL1 to GLn, and DL1 to DLm and pixels PX11 to PXnm. The signal lines GL1 to GLn and DL1 to DLm may include multiple gate lines GL1 to GLn and multiple data lines DL1 to DLm.

Each of the pixels PX11 to PXnm may be connected to a corresponding gate line among the gate lines GL1 to GLn and a corresponding data line among the data lines DL1 to DLm. Each of the pixels PX11 to PXnm may include a pixel driving circuit and a display element. Depending on the configuration of the pixel driving circuits of the pixels PX11 to PXnm, more types of signal lines may be provided on the display panel DP.

The gate driving circuit GDC may be integrated into the display panel DP through an oxide silicon gate driving circuit (OSG) process or an amorphous silicon gate driving circuit (ASG) process.

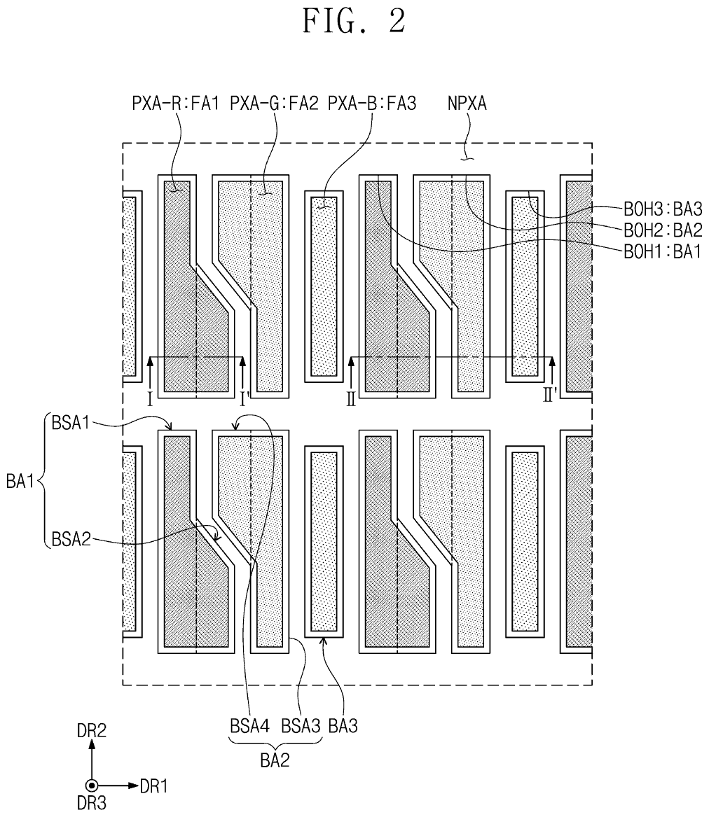

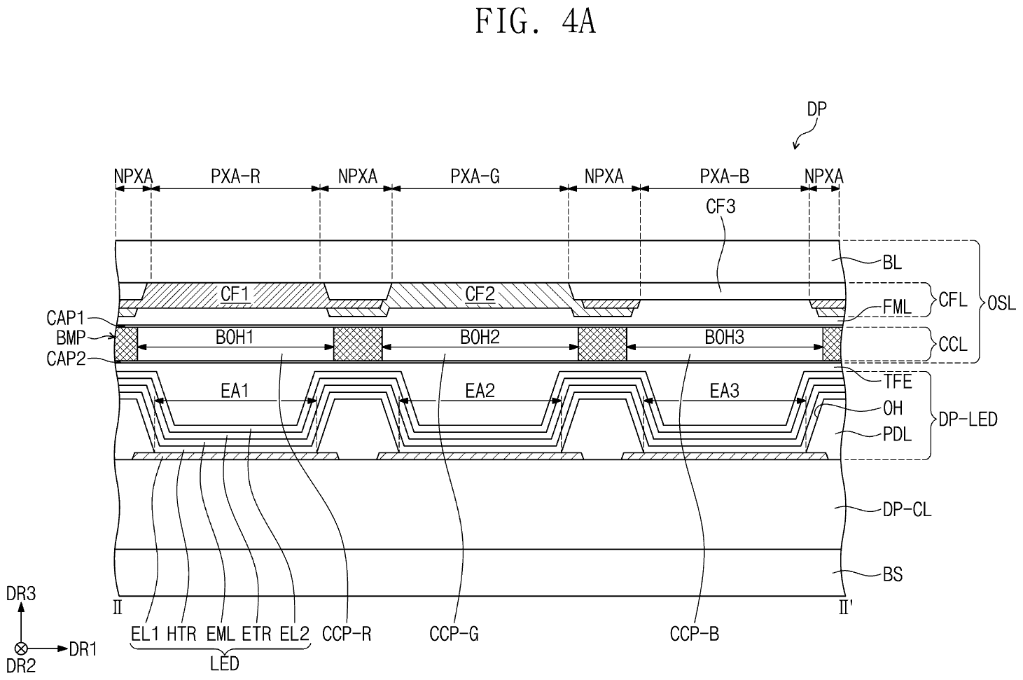

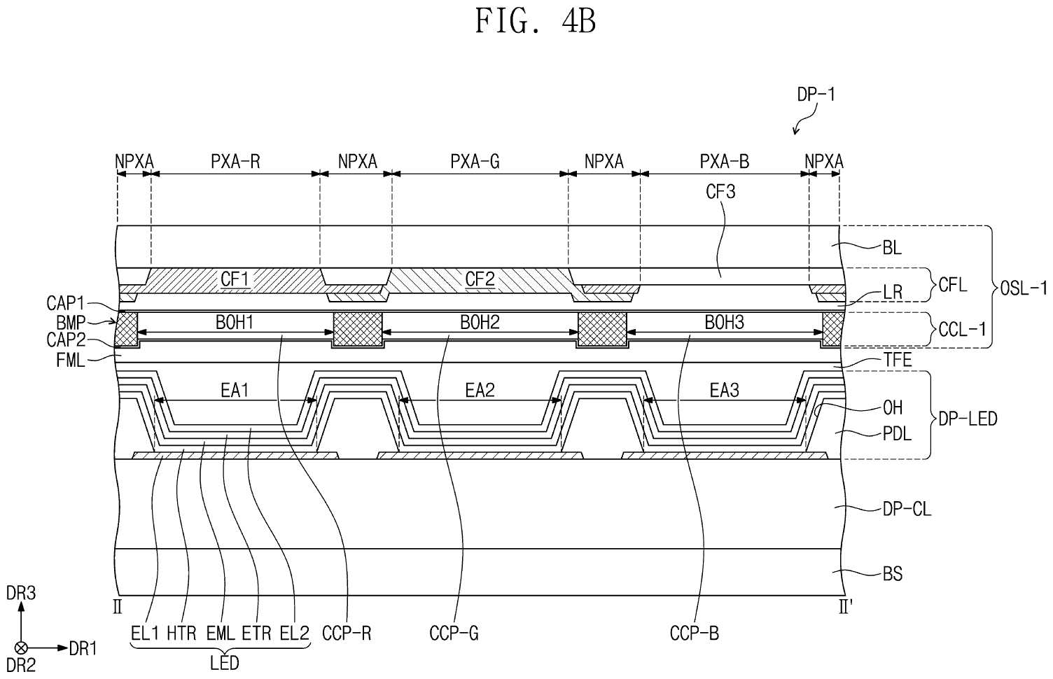

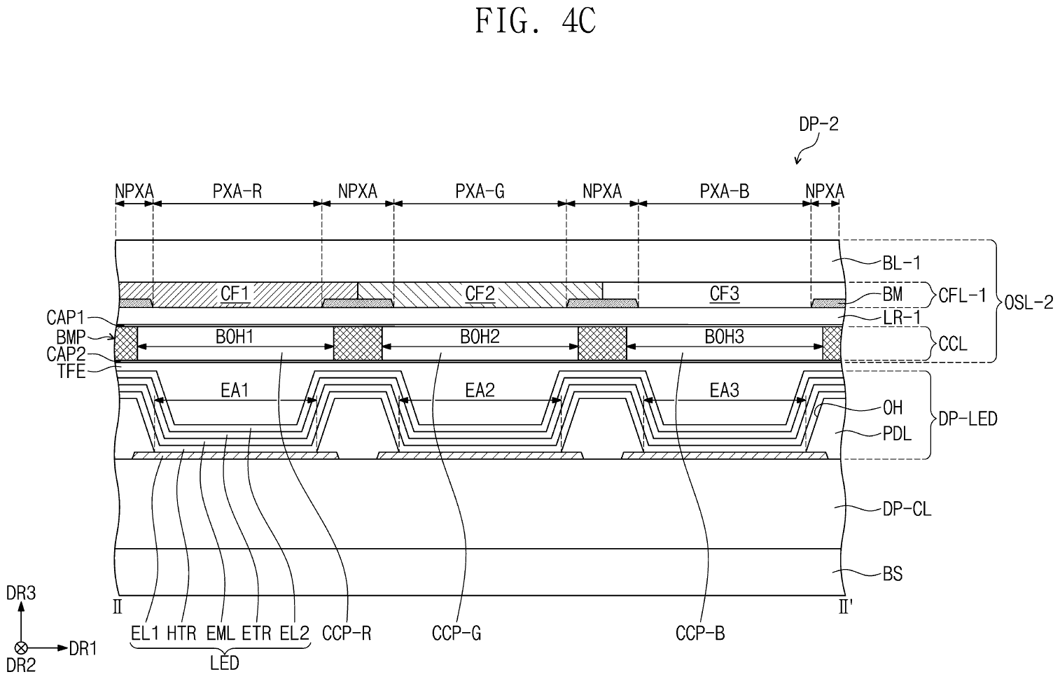

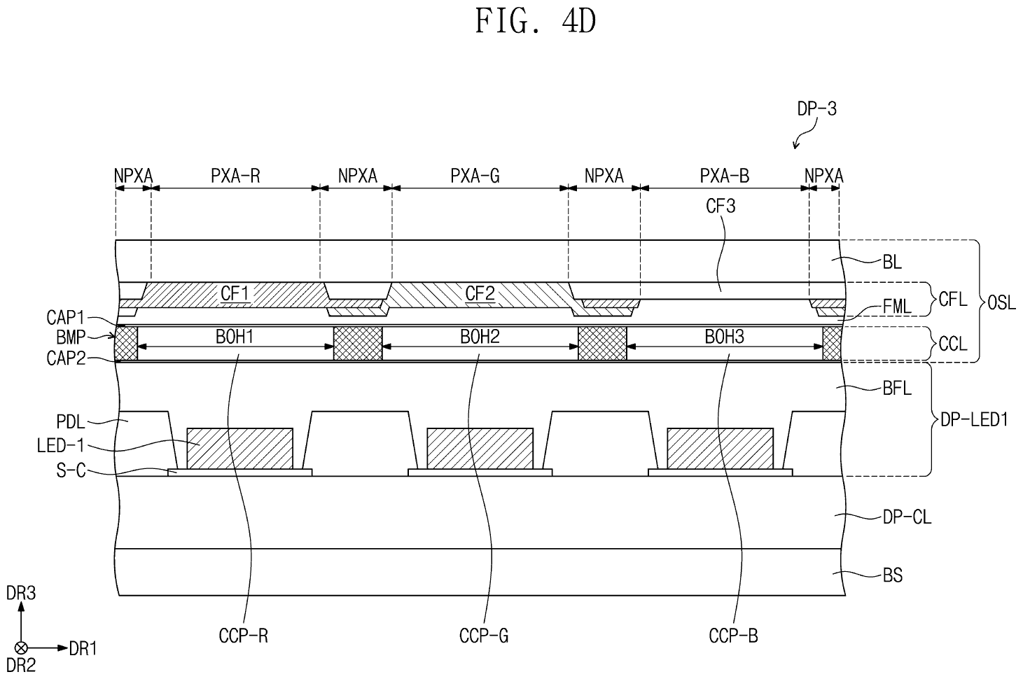

FIG. 2 is an enlarged plan view of a portion of the display panel according to an embodiment of the disclosure. FIG. 3 is a schematic cross-sectional view of a portion of the display panel according to an embodiment of the disclosure. Each of FIGS. 4A to 4D is a schematic cross-sectional view of a portion of the display panel according to an embodiment of the disclosure. FIG. 3 schematically illustrates a cross section corresponding to line I-I′ illustrated in FIG. 2. FIGS. 4A to 4D schematically illustrate cross sections corresponding to line II-II′ illustrated in FIG. 2.

FIG. 2 schematically illustrates the arrangement relationship of multiple pixel regions disposed in the display region DA of the display panel DP (see FIG. 1B) according to an embodiment of the disclosure. In an embodiment of the disclosure, the shapes of pixel regions PXA-R, PXA-G, and PXA-B illustrated in FIG. 2 may be repeatedly disposed throughout the display region DA (see FIG. 1B).

Referring to FIG. 2, a peripheral region NPXA may be disposed around the first to third pixel regions PXA-R, PXA-G, and PXA-B. The peripheral region NPXA may set the boundaries of the first to third pixel regions PXA-R, PXA-G, and PXA-B. The peripheral region NPXA may surround the first to third pixel regions PXA-R, PXA-G, and PXA-B.

The first to third pixel regions PXA-R, PXA-G, and PXA-B may correspond to first to third filter regions FA1, FA2, and FA3. Each of the first to third filter regions FA1, FA2, and FA3 may be a region defined by color filters that will be described below.

A structure, such as a pixel defining film PDL (see FIG. 3) or a bank BMP (see FIG. 3), which prevents color mixing between the first to third pixel regions PXA-R, PXA-G, and PXA-B, may be disposed in the peripheral region NPXA. Two or more of color filters to be described below may overlap each other in a plan view in the peripheral region NPXA.

As illustrated in FIG. 2, some of the first to third pixel regions PXA-R, PXA-G, and PXA-B may have a rectangular shape in a plan view. The rest of the first to third pixel regions PXA-R, PXA-G, and PXA-B may have a polygonal shape having a protruding portion protruding from a rectangular shape in a plan view. At least some of the first to third pixel regions PXA-R, PXA-G, and PXA-B may have a polygonal shape having a short side extending in the first direction DR1 and a long side extending in the second direction DR2. The areas of the first to third pixel regions PXA-R, PXA-G, and PXA-B may be set according to the colors of emitted light in a plan view. Among primary colors, the area of the pixel region that emits red light may be the largest, and the area of the pixel region that emits blue light may be the smallest. For example, the area of the first pixel region PXA-R that emits red light may be the largest, and the area of the third pixel region PXA-B that emits blue light may be the smallest.

FIG. 2 schematically illustrates the first to third pixel regions PXA-R, PXA-G, and PXA-B which have a rectangular shape or a polygonal shape, but the disclosure is not limited thereto. In a plan view, some of the first to third pixel regions PXA-R, PXA-G, and PXA-B may have different polygonal shapes (including substantially polygonal shapes). In an embodiment of the disclosure, in a plan view, the first to third pixel regions PXA-R, PXA-G, and PXA-B may have a rectangular shape (substantially rectangular shape) with rounded corners or a polygonal shape (substantially polygonal shape) with rounded corners.

One of the first to third pixel regions PXA-R, PXA-G, and PXA-B may provide red light, another one of the first to third pixel regions PXA-R, PXA-G, and PXA-B may provide blue light, and the remaining one of the first to third pixel regions PXA-R, PXA-G, and PXA-B may provide green light. In an embodiment, the first pixel region PXA-R may provide red light, the second pixel region PXA-G may provide green light, and the third pixel region PXA-B may provide blue light. In an embodiment, the first pixel region PXA-R may emit light in a wavelength range of about 620 nm to about 700 nm, the second pixel region PXA-G may emit light in aa wavelength range of about 520 nm to about 600 nm, and the third pixel region PXA-B may emit light in a wavelength range of about 410 nm to about 480 nm.

Although not illustrated, a bank well region may be defined in the display region DA. The bank well region may be a region in which a bank well is formed to prevent defects due to misplacement in the process of printing some of multiple light control patterns CCP-R, CCP-G, and CCP-B (see FIG. 4A) included in a light control layer CCL (see FIG. 4A). For example, the bank well region may be a region in which a bank well formed by removing a portion of a bank BMP (see FIG. 4A) is defined.

Referring to FIG. 3, the display panel DP according to an embodiment of the disclosure may include a base substrate BS, a circuit element layer DP-CL disposed on the base substrate BS, and a display element layer DP-LED disposed on the circuit element layer DP-CL. In this specification, the base substrate BS, the circuit element layer DP-CL, and the display element layer DP-LED may be collectively referred to as a lower panel.

The base substrate BS may be a member that provides a reference surface on which components included in the circuit element layer DP-CL are disposed. In an embodiment of the disclosure, the base substrate BS may be a glass substrate, a metal substrate, a polymer substrate, or the like. However, the disclosure is not limited thereto, and in another embodiment, the base substrate BS may be an inorganic layer, a functional layer, or a composite material layer.

The base substrate BS may have a multi-layered structure. For example, the base substrate BS may have a three-layer structure of a polymer resin layer, an adhesive layer, and a polymer resin layer. In an embodiment, the polymer resin layer may include a polyimide-based resin. In an embodiment, the polymer resin layer may include at least one of an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, and a perylene-based resin. In this specification, an “α-based” resin may be a resin including a functional group of “a”.

The circuit element layer DP-CL may be disposed on the base substrate BS. The circuit element layer DP-CL may include a transistor T-D as a circuit element. According to the design of the driving circuit of the pixel PX (see FIG. 1B), the configuration of the circuit element layer DP-CL may vary, and FIG. 3 schematically illustrates one transistor T-D according to an embodiment. The arrangement of an active A-D, a source S-D, a drain D-D, and a gate G-D constituting the transistor T-D is schematically illustrated in FIG. 3 according to an embodiment. The active A-D, the source S-D, and the drain D-D may be divided according to the doping concentration or conductivity of a semiconductor pattern.

The circuit element layer DP-CL may include a lower buffer layer BRL, a first insulating layer 10, a second insulating layer 20, and a third insulating layer 30 which are disposed on the base substrate BS. For example, the lower buffer layer BRL, the first insulating layer 10, and the second insulating layer 20 may be inorganic layers, and the third insulating layer 30 may be an organic layer.

The display element layer DP-LED may include a light-emitting element LED as a display element. The light-emitting element LED may generate source light. In an embodiment of the disclosure, the source light may be white light or blue light. In an embodiment, the display element layer DP-LED may include an organic light-emitting diode as a light-emitting element. For example, a light-emitting layer EML included in the light-emitting element LED may include an organic light-emitting material as a light-emitting material.

The light-emitting element LED may include a first electrode EL1, a second electrode EL2, and a light-emitting layer EML disposed between the first electrode EL1 and the second electrode EL2. In an embodiment, the display element layer DP-LED may include an organic light-emitting diode as a light-emitting element. In an embodiment of the disclosure, the light-emitting element may include a quantum dot light-emitting diode. For example, the light-emitting layer EML included in the light-emitting element LED may include an organic light-emitting material as a light-emitting material, or the light-emitting layer EML may include a quantum dot as a light-emitting material. In another embodiment, the display element layer DP-LED may include an ultra-small light-emitting element, which will be described below, as a light-emitting element. The ultra-small light-emitting element may include, for example, a micro LED element and/or a nano LED element. The ultra-small light-emitting element may have a micro or nano scale size and include an active layer disposed between multiple semiconductor layers.

The first electrode EL1 may be disposed on the third insulating layer 30. The first electrode EL1 may be connected directly or indirectly to the transistor T-D, and a connection structure between the first electrode EL1 and the transistor T-D is not illustrated in FIG. 3.

The display element layer DP-LED may include a pixel defining film PDL. For example, the pixel defining film PDL may be an organic layer. A light-emitting opening OH may be defined in the pixel defining film PDL. The light-emitting opening OH of the pixel defining film PDL may expose at least a portion of the first electrode EL1. In an embodiment, a first light-emitting region EA1 may be defined by the light-emitting opening OH.

A hole control layer HTR, a light-emitting layer EML, and an electron control layer ETR may overlap at least the pixel region PXA-R in a plan view. Each of the hole control layer HTR, the light-emitting layer EML, the electron control layer ETR, and the second electrode EL2 may be commonly disposed in the first to third pixel regions PXA-R, PXA-G, and PXA-B (see FIG. 4A). Each of the hole control layer HTR, the light-emitting layer EML, the electron control layer ETR, and the second electrode EL2 overlapping the first to third pixel regions PXA-R, PXA-G, and PXA-B (see FIG. 4A) may have an integral shape. Without being limited thereto, however, at least one of the hole control layer HTR, the light-emitting layer EML, and the electron control layer ETR may be separately formed in each of the first to third pixel regions PXA-R, PXA-G, and PXA-B (see FIG. 4A). In an embodiment of the disclosure, the light-emitting layer EML may be patterned in the light-emitting opening OH and separately formed in each of the first to third pixel regions PXA-R, PXA-G, and PXA-B (see FIG. 4A).

The hole control layer HTR may include a hole transport layer and may further include a hole injection layer.

The light-emitting layer EML may generate a third light which is source light. In an embodiment, the light-emitting layer EML may generate blue light. Blue light may have a wavelength in a range of about 410 nm to about 480 nm. The light-emitting spectrum of blue light may have a maximum peak in the wavelength range of about 440 nm to about 460 nm.

The electron control layer ETR may include an electron transport layer and may further include an electron injection layer.

The display element layer DP-LED may include a thin film encapsulation layer TFE that protects the second electrode EL2. The thin film encapsulation layer TFE may include an organic material or an inorganic material. The thin film encapsulation layer TFE may have a multi-layered structure in which an inorganic layer and an organic layer are repeated. In an embodiment, the thin film encapsulation layer TFE may include a first inorganic encapsulation layer IOL1, an organic encapsulation layer OL, and a second inorganic encapsulation layer IOL2. The first and second inorganic encapsulation layers IOL1 and IOL2 may protect the light-emitting element LED from external moisture, and the organic encapsulation layer OL may prevent the light-emitting element LED from defects caused by being damaged by foreign substances introduced during a manufacturing process. Although not illustrated, the display panel DP may further include a refractive index control layer on the thin film encapsulation layer TFE to improve light extraction efficiency.

As illustrated in FIG. 3, the optical structure layer OSL may be disposed on the thin film encapsulation layer TFE. The optical structure layer OSL may include a light control layer CCL, a low refractive layer LR, a color filter layer CFL, and a base layer BL. In this specification, the optical structure layer OSL may be referred to as an upper panel.

The light control layer CCL may be disposed on the display element layer DP-LED including the light-emitting element LED. The light control layer CCL may include a bank BMP, a first light control pattern CCP-R, and a first barrier layer CAP1.

The bank BMP may include a base resin and an additive. The base resin may be composed of a resin composition which may be generally referred to as a binder. The additive may include a coupling agent and/or a photoinitiator. The additive may further include a dispersant.

The bank BMP may include a black coloring agent to block light. The bank BMP may include a black dye and/or a black pigment mixed in the base resin. In an embodiment of the disclosure, the black coloring agent may include carbon black, or may include a metal such as chromium or an oxide thereof.

The bank BMP may include a first bank opening BOH1 corresponding to the light-emitting opening OH. In a plan view, the first bank opening BOH1 may overlap the light-emitting opening OH and may have a larger area than the light-emitting opening OH in a plan view. For example, the first bank opening BOH1 may have a larger area than the first light-emitting region EA1 defined by the light-emitting opening OH. In this specification, the expression “One element corresponds to another element” may mean that two elements overlap each other in the thickness direction DR3 of the display panel DP and is not limited to having a same area.

The first light control pattern CCP-R may be disposed inside the first bank opening BOH1. The first light control pattern CCP-R may change the optical properties of source light.

The first light control pattern CCP-R may include a quantum dot to change the optical properties of source light. The first light control pattern CCP-R may include a first quantum dot that converts source light into light of a different wavelength. In the first light control pattern CCP-R overlapping the first pixel region PXA-R, the first quantum dot may convert source light into red light.

In this specification, a “quantum dot” may be a crystal of a semiconductor compound. The quantum dot may emit light of various light-emitting wavelengths depending on the size of the crystal. The quantum dot may emit light of various light-emitting wavelengths by adjusting the element ratio of the quantum dot compound.

The diameter of the quantum dot may be, for example, in a range of about 1 nm to about 10 nm.

The quantum dot may be synthesized by a wet chemical process, a metal organic chemical vapor deposition process, a molecular beam epitaxy process, or a process similar thereto.

The wet chemical process is a method of mixing an organic solvent and a precursor material to each other and growing a quantum dot particle crystal. In case that the crystal grows, the organic solvent may naturally act as a dispersant coordinated on the surface of the quantum dot crystal and control the growth of the crystal. Therefore, the wet chemical process may be more readily performed than a vapor deposition method such as a metal organic chemical vapor deposition (MOCVD) process or a molecular beam epitaxy (MBE) process, and it may be possible to control the growth of quantum dot particles through a low-cost process.

The core of the quantum dot may include a group II-VI compound, a group III-V compound, a group III-VI compound, a group I-III-VI compound, a group II-IV-V compound, a group IV-VI compound, a group IV element, a group IV compound, or a combination thereof.

The group II-VI compound may include: a binary compound such as CdSe, CdTe, CdS, ZnS, ZnSe, ZnTe, ZnO, HgS, HgSe, HgTe, MgSe, MgS, and a mixture thereof; a ternary compound such as CdSeS, CdSeTe, CdSTe, ZnSeS, ZnSeTe, ZnSTe, HgSeS, HgSeTc, HgSTe, CdZnS, CdZnSc, CdZnTe, CdHgS, CdHgSe, CdHgTe, HgZnS, HgZnSc, HgZnTc, MgZnSc, MgZnS, and a mixture thereof; and a quaternary compound such as HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof. In an embodiment, the group II-VI semiconductor compound may further include a group I metal and/or a group IV element. A group I-II-VI compound may include CuSnS or CuZnS, and a Group II-IV-VI compound may include ZnSnS or the like. A group I-II-IV-VI compound may include a quaternary compound such as Cu₂ZnSnS₂, Cu₂ZnSnS₄, Cu₂ZnSnSc₄, Ag₂ZnSnS₂, and a mixture thereof.

The group III-VI compound may include a binary compound such as In₂S₃ and In₂Sc₃, a ternary compound such as InGaS₃ and InGaSe₃, or a combination thereof.

The group I-III-VI compound may include a ternary compound such as AgInS, AgInS₂, CuInS, CuInS₂, AgGaS₂, CuGaS₂CuGaO₂, AgGaO₂, AgAlO₂, and a mixture thereof, or a quaternary compound such as AgInGaS₂, and CuInGaS₂.

The group III-V compound may include: a binary compound such as GaN, GaP, GaAs, GaSb, AlN, AlP, AlAs, AlSb, InN, InP, InAs, InSb, and a mixture thereof; a ternary compound such as GaNP, GaNAs, GaNSb, GaPAs, GaPSb, AlNP, AlNAs, AlNSb, AlPAS, AlPSb, InGaP, InAlP, InNP, InNAs, InNSb, InPAs, InPSb, and a mixture thereof; and a quaternary compound such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof. In an embodiment, the group III-V compound may further include a group II metal. For example, the group III-II-V compound may include InZnP and the like.

The group IV-VI compound may include: a binary compound such as SnS, SnSc, SnTe, PbS, PbSe, PbTe, and a mixture thereof; a ternary compound such as SnSeS, SnSeTe, SnSTe, PbSeS, PbSeTe, PbSTe, SnPbS, SnPbSe, SnPbTe, and a mixture thereof; and a quaternary compound such as SnPbSSe, SnPbSeTe, SnPbSTe, and a mixture thereof.

An example of the group II-IV-V compound may be a ternary compound such as ZnSnP, ZnSnP₂, ZnSnAs₂, ZnGcP₂, ZnGeAs₂, CdSnP₂, CdGeP₂, and a mixture thereof.

The group IV element may include Si, Ge, and a mixture thereof. The group IV compound may include a binary compound such as SiC, SiGe, and a mixture thereof.

Each element included in multi-element compounds, such as a binary compound, a ternary compound, and a quaternary compound, may be present in a particle at a uniform or non-uniform concentration. For example, the above chemical formulas may indicate types of elements included in the compounds, and the ratios of elements in the compounds may be different from each other. For example, AgInₓGa₁₋ₓS₂ (x is a real number between 0 and 1) may include AgInGaS₂.

In an embodiment, the binary compounds, the ternary compounds, or the quaternary compounds may be present in a particle at a uniform concentration, or may be present in a same particle by being divided into states in which the concentration distributions are partially different from one another. In an embodiment, the quantum dots may have a core/shell structure in which a quantum dot surrounds another quantum dot. The core/shell structure may have a concentration gradient in which the concentration of an element present in the shell gradually decreases toward the core.

In some embodiments of the disclosure, the quantum dots may have a core-shell structure including: a core including a nanocrystal described above; and a shell surrounding the core. The shell of the quantum dots may serve as a protective layer for maintaining semiconductor characteristics by preventing the chemical modification of the core and/or as a charging layer for imparting electrophoretic characteristics to the quantum dots. The shell may be single-layered or multi-layered. In an embodiment, the shell of the quantum dots may include a metal oxide, a non-metal oxide, a semiconductor compound, or a combination thereof.

For example, the metal or non-metal oxide may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, and NiO, or a ternary compound such as MgAl₂O₄, CoFe₂O₄, NiFe₂O₄, and CoMn₂O₄, but the disclosure is not limited thereto.

Examples of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, and the like, but the disclosure is not limited thereto.

The quantum dot may have a full width of half maximum (FWHM) of a light-emitting wavelength spectrum less than or equal to about 45 nm. For example, the quantum dot may have a full width of half maximum (FWHM) of a light-emitting wavelength spectrum less than or equal to about 40 nm. For example, the quantum dot may have a full width of half maximum (FWHM) of a light-emitting wavelength spectrum less than or equal to about 30 nm. Within those ranges, it may be possible to improve color purity or color reproducibility. Since light emitted through the quantum dot is emitted in all directions, a wide viewing angle may be improved.

The shape of the quantum dot is not particularly limited to those generally used in the art, and a shape such as a spherical, pyramidal, multi-armed, or cubic nanoparticle, nanotube, nanowire, nanofiber, and nanoplate particle may be used.

Since an energy band gap may be controlled by adjusting the size of the quantum dot or the ratio of elements in a quantum dot compound, it may be possible to obtain light of various wavelengths from a quantum dot light-emitting layer. Therefore, by using the quantum dot described above (using quantum dots of different sizes or different element ratios in the quantum dot compound), it may be possible to implement a light-emitting element configured to emit light of various wavelengths. For example, the control of the size of the quantum dot or the ratio of elements in the quantum dot compound may be selected so as to emit red light, green light, and/or blue light. In another embodiment, the quantum dots may be configured to emit white light by combining light of various colors.

In an embodiment of the disclosure, the quantum dot included in the first light control pattern CCP-R overlapping the first pixel region PXA-R in a plan view may have a red light-emitting color. In case that the particle size of a quantum dot is smaller, light of a shorter wavelength range may be emitted. For example, among quantum dots having a same core, the quantum dots emitting green color light may have a smaller particle size than the quantum dots emitting red color light. Among quantum dots having a same core, the quantum dots emitting blue color light may have a smaller particle size than the quantum dots emitting green color light. However, the disclosure is not limited thereto, and even among quantum dots having a same core, the particle size may be adjusted according to a shell-forming material, a shell thickness, and the like.

In case that the quantum dots have various light-emitting colors such as a blue color, a red color, or a green color, the quantum dots having different light-emitting colors may respectively have different core materials.

The first light control pattern CCP-R may further include a scatterer. The first light control pattern CCP-R may include a first quantum dot, which converts blue light into red light, and a scatterer which scatters light.

The scatterer may be an inorganic particle. For example, the scatterer may include at least one of TiO₂, ZnO, Al₂O₃, SiO₂, hollow silica, or a mixture thereof.

The first light control pattern CCP-R may include a base resin that disperses first quantum dots and scatterers. The base resin may be a medium, in which the first quantum dots and the scatterers are dispersed, and may be made of a resin composition which may generally be referred to as a binder. For example, the base resin may be an acrylic-based resin, a urethane-based resin, a silicone-based resin, an epoxy-based resin, or the like. The base resin may be a transparent resin.

In an embodiment, the first light control pattern CCP-R may be formed by an inkjet process. A liquid composition may be provided in the bank opening BOH1. The volume of the composition which is polymerized through a heat curing process or a light curing process may be reduced after curing.

The light control layer CCL may include a first barrier layer CAP1 disposed on a surface of the first light control pattern CCP-R. The first barrier layer CAP1 may serve to prevent the penetration of moisture and/or oxygen (hereinafter referred to as ‘moisture/oxygen’) and improve the optical properties of the optical structure layer OSL by adjusting a refractive index. The first barrier layer CAP1 may be disposed on an upper or lower surface of the first light control pattern CCP-R so as to be able to block the first light control pattern CCP-R from being exposed to moisture/oxygen, and for example, the quantum dots included in the first light control pattern CCP-R may be blocked from being exposed to moisture/oxygen. The first barrier layer CAP1 may also protect the first light control pattern CCP-R from an external impact.

In an embodiment of the disclosure, the first barrier layer CAP1 may be spaced apart from the display element layer DP-LED with the first light control pattern CCP-R interposed between the first barrier layer CAP1 and the display element layer DP-LED. For example, the first barrier layer CAP1 may be disposed on the upper surface of the first light control pattern CCP-R. In an embodiment of the disclosure, a second barrier layer CAP2 may be disposed between the first light control pattern CCP-R and the display element layer DP-LED. The first barrier layer CAP1 may cover the upper surface of the first light control pattern CCP-R adjacent to the low refractive layer LR, and the second barrier layer CAP2 may cover the lower surface of the first light control pattern CCP-R adjacent to the display element layer DP-LED. In this specification, the “upper surface” may be a surface located at the top, based on the third direction DR3, and the “lower surface” may be a surface located at the bottom, based on the third direction DR3.

In an embodiment, the first barrier layer CAP1 and the second barrier layer CAP2 may each cover a surface of the bank BMP as well as the first light control pattern CCP-R.

The first barrier layer CAP1 may cover a surface of the bank BMP and the first light control pattern CCP-R adjacent to the low refractive layer LR. The first barrier layer CAP1 may be disposed below (e.g., directly below) the low refractive layer LR. The second barrier layer CAP2 may be disposed on (e.g., directly on) the thin film encapsulation layer TFE. The light control layer CCL may be disposed on the display element layer DP-LED and the thin film encapsulation layer TFE with the second barrier layer CAP2 interposed between the light control layer CCL and the thin film encapsulation layer TFE. The light control patterns CCP-R, CCP-G, and CCP-B of the light control layer CCL may be formed in a continuous process on the second barrier layer CAP2 disposed on the thin film encapsulation layer TFE.

The first barrier layer CAP1 and the second barrier layer CAP2 may include an inorganic material. In the display panel DP according to an embodiment of the disclosure, the first barrier layer CAP1 may include silicon oxynitride (SiON). Both the first barrier layer CAP1 and the second barrier layer CAP2 may include silicon oxynitride. Without being limited thereto, however, each of the first barrier layer CAP1 and the second barrier layer CAP2 may include silicon oxide (SiOₓ) or silicon nitride (SiNₓ). In an embodiment of the disclosure, the first barrier layer CAP1 disposed on the first light control pattern CCP-R may include silicon oxynitride and the second barrier layer CAP2 disposed below the first light control pattern CCP-R may include silicon oxide.

A color filter layer CFL may be disposed on the light control layer CCL. The color filter layer CFL may include at least one color filter. The color filter may transmit light of a specific wavelength range and block light outside the wavelength range. A first color filter CF1 corresponding to the first pixel region PXA-R may transmit red light and block green light and blue light.

The first color filter CF1 may include a base resin and dye and/or pigment dispersed in the base resin. The base resin may be a medium, in which dye and/or pigment are dispersed, and may be made of a resin composition which may be generally referred to as a binder.

The first color filter CF1 may have a uniform thickness in the first pixel region PXA-R. Light converted from blue light, which is source light, to red light through the first light control pattern CCP-R may be provided to the outside with uniform luminance in the first pixel region PXA-R.

The optical structure layer OSL may further include a filling layer FML disposed between the light control layer CCL and the color filter layer CFL. In an embodiment of the disclosure, the filling layer FML may fill a space between the light control layer CCL and the color filter layer CFL. The filling layer FML may be disposed on (e.g., directly on) the first barrier layer CAP1, and the color filter layer CFL may be disposed on (e.g., directly on) the filling layer FML. The lower surface of the filling layer FML may be in contact with the upper surface of the first barrier layer CAP1, and the upper surface of the filling layer FML may be in contact with the lower surfaces of color filters CF1, CF2, and CF3 of the color filter layer CFL.

The filling layer FML may function as a buffer between the light control layer CCL and the color filter layer CFL. In an embodiment of the disclosure, the filling layer FML may function as a shock absorber or the like and increase the strength of the display panel DP. The filling layer FML may be formed from a filling resin including a polymer resin. For example, the filling layer FML may be formed from a filling resin including an acrylic-based resin, an epoxy-based resin, or the like.

By being disposed between the light control layer CCL and the color filter layer CFL, the filling layer FML may also function as an optical functional layer to increase light extraction efficiency or prevent reflected light from entering the light control layer CCL. The filling layer FML may have a lower refractive index than an adjacent layer.

In an embodiment of the disclosure, the display panel DP may further include a base layer BL disposed on the color filter layer CFL. The base layer BL may be a member that provides a reference surface on which the color filter layer CFL, the low refractive layer LR, and the light control layer CCL are disposed. The base layer BL may be a glass substrate, a metal substrate, or a plastic substrate. However, the disclosure is not limited thereto, and the base layer BL may be an inorganic layer, an organic layer, or a composite material layer. Unlike what is illustrated, in another embodiment of the disclosure, the base layer BL may be omitted.

Although not illustrated, an anti-reflection layer may be disposed on the base layer BL. The anti-reflection layer may reduce the reflectance of external light incident from the outside. The anti-reflection layer may selectively transmit light emitted from the display panel DP. In an embodiment of the disclosure, the anti-reflection layer may be a single layer including dye and/or pigment dispersed in the base resin. The anti-reflection layer may be provided as one continuous layer that completely overlaps the entire first to third pixel regions PXA-R, PXA-G, and PXA-B (see FIG. 4A) in a plan view.

The anti-reflection layer may not include a polarizing layer. Accordingly, light directed toward the display element layer DP-LED through the anti-reflection layer may not be polarized. The display element layer DP-LED may receive unpolarized light from above the anti-reflection layer.

Referring to FIG. 4A, the display panel DP may include a base substrate BS and a circuit element layer DP-CL disposed on the base substrate BS. The circuit element layer DP-CL may be disposed on the base substrate BS. The circuit element layer DP-CL may include an insulating layer, a semiconductor pattern, a conductive pattern, and a signal line. An insulating layer, a semiconductor layer, and a conductive layer may be formed on the base substrate BS by coating, deposition or the like, and the insulating layer, the semiconductor layer, and the conductive layer may be selectively patterned through multiple photolithography processes. Accordingly, a semiconductor pattern, a conductive pattern, and a signal line included in the circuit element layer DP-CL may be formed. In an embodiment of the disclosure, the circuit element layer DP-CL may include a transistor, a buffer layer, and multiple insulating layers.

The light-emitting element LED according to an embodiment of the disclosure may include a first electrode EL1, a second electrode EL2 configured to face the first electrode EL1, and a light-emitting layer EML disposed between the first electrode EL1 and the second electrode EL2. The light-emitting layer EML included in the light-emitting element LED may include an organic light-emitting material or a quantum dot as a light-emitting material. The light-emitting element LED may further include a hole control layer HTR and an electron control layer ETR. Although not illustrated, the light-emitting element LED may further include a capping layer (not illustrated) disposed on the second electrode EL2.

The pixel defining film PDL may be disposed on the circuit element layer DP-CL and cover a portion of the first electrode EL1. A light-emitting opening OH may be defined in the pixel defining film PDL. The light-emitting opening OH of the pixel defining film PDL may expose at least a portion of the first electrode EL1. In an embodiment, light-emitting regions EA1, EA2, and EA3 may correspond to a partial region of the first electrode EL1 exposed by the light-emitting opening OH.

The display element layer DP-LED may include a first light-emitting region EA1, a second light-emitting region EA2, and a third light-emitting region EA3. The first light-emitting region EA1, the second light-emitting region EA2, and the third light-emitting region EA3 may be divided by the pixel defining film PDL. The first light-emitting region EA1, the second light-emitting region EA2, and the third light-emitting region EA3 may respectively correspond to the first pixel region PXA-R, the second pixel region PXA-G, and the third pixel region PXA-B.

The light-emitting regions EA1, EA2, and EA3 may overlap the pixel regions PXA-R, PXA-G, and PXA-B in a plan view. In a plan view, the areas of the pixel regions PXA-R, PXA-G, and PXA-B divided by the color filters CF1, CF2, and CF3 and the areas of the light-emitting regions EA1, EA2, and EA3 may be substantially the same.

In the light-emitting element LED, the first electrode EL1 may be disposed on the circuit element layer DP-CL. The first electrode EL1 may be an anode or a cathode. In another embodiment, the first electrode EL1 may be a pixel electrode. The first electrode EL1 may be a transmissive electrode, a semi-transmissive electrode, or a reflective electrode.

The hole control layer HTR may be disposed between the first electrode EL1 and the light-emitting layer EML. The hole control layer HTR may include at least one of a hole injection layer, a hole transport layer, and an electron blocking layer. The hole control layer HTR may be disposed as a common layer so as to overlap the light-emitting regions EA1, EA2, and EA3 and the entire pixel defining film PDL that separates the light-emitting regions EA1, EA2, and EA3 in a plan view. However, the disclosure is not limited thereto, and the hole control layer HTR may be patterned and provided so as to be separately disposed to correspond to each of the light-emitting regions EA1, EA2, and EA3.

The light-emitting layer EML may be disposed on the hole control layer HTR. In an embodiment of the disclosure, the light-emitting layer EML may be provided as a common layer so as to overlap the light-emitting regions EA1, EA2, and EA3 and the entire pixel defining film PDL that separates the light-emitting regions EA1, EA2, and EA3 in a plan view. In an embodiment of the disclosure, the light-emitting layer EML may emit blue light. The light-emitting layer EML may entirely overlap the hole control layer HTR and the electron control layer ETR in a plan view.

However, the disclosure is not limited thereto, and in another embodiment of the disclosure, the light-emitting layer EML may be disposed in the light-emitting opening OH. For example, the light-emitting layer EML may be separately formed so as to correspond to the light-emitting regions EA1, EA2, and EA3 divided by the pixel defining film PDL. The light-emitting layers EML separately formed so as to correspond to the light-emitting regions EA1, EA2, and EA3 may all emit blue light or may emit light of different wavelength ranges.

The light-emitting layer EML may have a single-layered structure composed of a single material, a single-layered structure composed of different materials, or a multi-layered structure having layers composed of different materials. The light-emitting layer EML may include a fluorescent or phosphorescent material. In the light-emitting element LED according to an embodiment of the disclosure, the light-emitting layer EML may include a light-emitting material such as an organic light-emitting material, a metal organic complex, or a quantum dot. FIGS. 3 and 4A schematically illustrate the light-emitting element LED including one light-emitting layer EML according to an embodiment, but the disclosure is not limited thereto, and in another embodiment of the disclosure, the light-emitting element LED may include multiple light-emitting stacks each including at least one light-emitting layer.

FIG. 5 is a schematic cross-sectional view of a light-emitting element according to an embodiment of the disclosure. Unlike the light-emitting element illustrated in FIGS. 3 and 4A, FIG. 5 schematically illustrates a light-emitting element LED including multiple light-emitting stacks ST1, ST2, ST3, and ST4 according to an embodiment.

Referring to FIG. 5, the light-emitting element LED according to an embodiment of the disclosure may include a first electrode EL1, a second electrode EL2 configured to face the first electrode EL1, and first to fourth light-emitting stacks ST1, ST2, ST3, and ST4 disposed between the first electrode EL1 and the second electrode EL2. FIG. 5 schematically illustrates that the light-emitting element LED includes four light-emitting stacks according to an embodiment, but the disclosure is not limited thereto, and the number of the light-emitting stacks included in the light-emitting element LED may be less or more than four.

The light-emitting element LED may include first to third charge generation layers CGL1, CGL2, and CGL3 disposed between adjacent ones of the first to fourth light-emitting stacks ST1, ST2, ST3, and ST4.

In case that a voltage is applied, each of the first to third charge generation layers CGL1, CGL2, and CGL3 may generate charges (electrons and holes) by forming a complex through an oxidation-reduction reaction. The first to third charge generation layers CGL1, CGL2, and CGL3 may respectively provide the generated charges to the stacks ST1, ST2, ST3, and ST4 adjacent to the charge generation layer CGL1, CGL2, or CGL3. The first to third charge generation layers CGL1, CGL2, and CGL3 may double the efficiency of currents generated in the stacks ST1, ST2, ST3, and ST4 adjacent to the charge generation layer CGL1, CGL2, or CGL3 and play a role in controlling the balance of charges between the stacks ST1, ST2, ST3, and ST4 adjacent to the charge generation layer CGL1, CGL2, or CGL3.

Each of the first to third charge generation layers CGL1, CGL2, and CGL3 may include an n-type layer and a p-type layer. The first to third charge generation layers CGL1, CGL2, and CGL3 may each have a structure in which the n-type layer and the p-type layer are bonded to each other. Without being limited thereto, however, the first to third charge generation layers CGL1, CGL2, and CGL3 may include only one of the n-type layer and the p-type layer. The n-type layer may be a charge generation layer that provides electrons to an adjacent stack. The n-type layer may be a layer in which an n-dopant is doped in a base material. The p-type layer may be a charge generation layer that provides holes to an adjacent stack. The p-type layer may be a layer in which a p-dopant is doped in a base material.

In an embodiment of the disclosure, the thickness of each of the first to third charge generation layers CGL1, CGL2, and CGL3 may be in a range of about 1 Angstrom (A) to about 150 Angstroms (Å). The concentration of the n-dopant doped in the first to third charge generation layers CGL1, CGL2, and CGL3 may be in a range of about 0.1% to about 3%. For example, the concentration of the n-dopant doped in the first to third charge generation layers CGL1, CGL2, and CGL3 may be in a range of about 0.1% to about 1%. In case that the concentration is less than about 0.1%, the effect of the first to third charge generation layers CGL1, CGL2, and CGL3 which control the balance of charges may hardly occur. In case that the concentration is greater than about 3%, the light efficiency of the light-emitting element LED may be reduced.

Each of the first to third charge generation layers CGL1, CGL2, and CGL3 may include a charge generation compound composed of an arylamine-based organic compound, a metal, a metal oxide, a metal carbide, a metal fluoride, or a mixture thereof. For example, the arylamine-based organic compound may include α-NPD, 2-TNATA, TDATA, MTDATA, sprio-TAD, or sprio-NPB. The metal may include cesium (Cs), molybdenum (Mo), vanadium (V), titanium (Ti), tungsten (W), barium (Ba), or lithium (Li). The metal oxide, the metal carbide, and the metal fluoride may include Re₂O₇, MoO₃, V₂O₅, WO₃, TiO₂, Cs₂CO₃, BaF, LiF, or CsF. However, the materials of the first to third charge generation layers CGL1, CGL2, and CGL3 are not limited to the above examples.

Each of the first to fourth light-emitting stacks ST1, ST2, ST3, and ST4 may include a light-emitting layer. The first light-emitting stack ST1 may include a first light-emitting layer BEML1, the second light-emitting stack ST2 may include a second light-emitting layer BEML2, the third light-emitting stack ST3 may include a third light-emitting layer BEML3, and the fourth light-emitting stack ST4 may include a fourth light-emitting layer GEML. Some of the light-emitting layers included in the first to fourth light-emitting stacks ST1, ST2, ST3, and ST4 may emit light of substantially a same color, and some of the light-emitting layers included in the first to fourth light-emitting stacks ST1, ST2, ST3, and ST4 may emit light of different colors.

In an embodiment of the disclosure, the first to third light-emitting layers BEML1, BEML2, and BEML3 of the first to third light-emitting stacks ST1, ST2, and ST3 may emit substantially a same first color light. For example, the first color light may be blue light which is the source light described above. The wavelength range of light emitted from the first to third light-emitting layers BEML1, BEML2, and BEML3 may be in a range of about 420 nm to about 480 nm.

The fourth light-emitting layer GEML of the fourth light-emitting stack ST4 may emit a second color light different from the first color light. For example, the second color light may be green light. The wavelength range of light emitted from the fourth light-emitting layer GEML may be in a range of about 520 nm to about 600 nm.

The light-emitting element LED may emit light in a direction from the first electrode EL1 to the second electrode EL2. In the light-emitting element LED according to an embodiment of the disclosure, the stacks ST1, ST2, ST3, and ST4 may respectively include hole transport regions HTR1, HTR2, HTR3, and HTR4 and electron transport regions ETR1, ETR2, ETR3, and ETR4. The hole transport regions HTR1, HTR2, HTR3, and HTR4 may transmit holes, which are provided from the first electrode EL1 or the charge generation layers CGL1, CGL2, and CGL3, to the light-emitting layer. The electron transport regions ETR1, ETR2, ETR3, and ETR4 may transmit electrons, which are provided from the second electrode EL2 or the charge generation layers CGL1, CGL2, and CGL3, to the light-emitting layer.

It is schematically illustrated that, based on the direction in which light is emitted, the light-emitting element LED according to an embodiment of the disclosure has a structure in which the hole transport regions HTR1, HTR2, HTR3, and HTR4 are disposed below the light-emitting layers BEML1, BEML2, BEML3, and GEML included in the stacks ST1, ST2, ST3, and ST4, and the electron transport regions ETR1, ETR2, ETR3, and ETR4 are disposed on the light-emitting layers BEML1, BEML2, BEML3, and GEML included in the stacks ST1, ST2, ST3, and ST4. For example, the light-emitting element LED according to an embodiment of the disclosure may have a forward element structure. Without being limited thereto, however, based on the direction in which light is emitted, the light-emitting element LED according to an embodiment of the disclosure may have an inverted element structure in which the electron transport regions ETR1, ETR2, ETR3, and ETR4 are disposed below the light-emitting layers BEML1, BEML2, BEML3, and GEML included in the stacks ST1, ST2, ST3, and ST4 and the hole transport regions HTR1, HTR2, HTR3, and HTR4 are disposed on the light-emitting layers BEML1, BEML2, BEML3, and GEML included in the stacks ST1, ST2, ST3, and ST4.

The hole transport regions HTR1, HTR2, HTR3, and HTR4 may respectively include hole injection layers HIL1, HIL2, HIL3, and HIL4 and hole transport layers HTL1, HTL2, HTL3, and HTL4 disposed on the hole injection layers HIL1, HIL2, HIL3, and HIL4. The hole transport layers HTL1, HTL2, HTL3, and HTL4 may be in contact with the lower surface of the light-emitting layer. Without being limited thereto, however, the hole transport regions HTR1, HTR2, HTR3, and HTR4 may further include a hole-side additional layer disposed on the hole transport layers HTL1, HTL2, HTL3, and HTL4. The hole-side additional layer may include at least one of a hole buffer layer, a light-emitting auxiliary layer, or an electron blocking layer. The hole buffer layer may increase light-emitting efficiency by compensating for a resonance distance depending on the wavelength of light emitted from the light-emitting layer. The electron blocking layer may serve to prevent electrons from being injected from the electron transport regions to the hole transport regions.

The electron transport regions ETR1, ETR2, ETR3, and ETR4 may include an electron transport layer. The electron transport regions ETR1, ETR2, ETR3, and ETR4 may further include an electron injection layer disposed on the electron transport layer. For example, a fourth electron transport region ETR4 included in the fourth light-emitting stack ST4 may further include a fourth electron injection layer EIL4 disposed on a fourth electron transport layer ETL4. The electron transport regions ETR1, ETR2, ETR3, and ETR4 may further include an electron-side additional layer disposed between the electron transport layer and the light-emitting layer. The electron-side additional layer may include at least one of an electron buffer layer or a hole blocking layer.

In the light-emitting element LED according to an embodiment of the disclosure, the first electrode EL1 may be a reflective electrode. For example, the first electrode EL1 may include Ag, Mg, Cu, Al, Pt, Pd, Au, Ni, Nd, Ir, Cr, Li, Ca, LiF/Ca, LiF/Al, Mo, Ti, W, In, Zn, Sn, or a compound or mixture thereof (for example, a mixture of Ag and Mg), which has a high reflectance. In another embodiment, the first electrode EL1 may have a multi-layered structure including: a reflective film formed of the above materials; and a transparent conductive film formed at least one of indium tin oxide (ITO), indium zinc oxide (IZO), zinc oxide (ZnO), indium tin zinc oxide (ITZO), and the like. For example, the first electrode EL1 may have a two-layer structure of ITO/Ag or a three-layer structure of ITO/Ag/ITO, but the disclosure is not limited thereto. In another embodiment, the first electrode EL1 may include an above-described metal material, a combination of two or more metal materials selected from among the above-described metal materials, an oxide of the above-described metal materials, or the like. The thickness of the first electrode EL1 may be in a range of about 70 nm to about 1000 nm. For example, the thickness of the first electrode EL1 may be in a range of about 100 nm to about 300 nm.

In the light-emitting element LED according to an embodiment of the disclosure, each of the hole transport regions HTR1, HTR2, HTR3, and HTR4 may have a single-layered structure made of a single material, a single-layered structure made of different materials, or a multi-layered structure having layers made of different materials.

Each of the hole transport regions HTR1, HTR2, HTR3, and HTR4 may be formed by using a method such as a vacuum deposition method, a spin coating method, a casting method, a Langmuir-Blodgett (LB) method, an inkjet printing method, a laser printing method, and a laser induced thermal imaging (LITI) method.

Each of the hole transport regions HTR1, HTR2, HTR3, and HTR4 may include a phthalocyanine compound such as copper phthalocyanine, DNTPD(N1,N1′-([1,1′-biphenyl]-4,4′-diyl)bis(N1-phenyl-N4,N4-di-m-tolylbenzene-1,4-diamine)), m-MTDATA(4,4′,4″-[tris(3-methylphenyl)phenylamino]triphenylamine), TDATA(4,4′,4″-Tris(N,N-diphenylamino)triphenylamine), 2-TNATA(4,4′,4″-tris[N (2-naphthyl)-N-phenylamino]-triphenylamine), PEDOT/PSS(Poly(3,4-ethylenedioxythiophene)/Poly(4-styrenesulfonate)), PANI/DBSA(Polyaniline/Dodecylbenzenesulfonic acid), PANI/CSA(Polyaniline/Camphor sulfonicacid), PANI/PSS(Polyaniline/Poly(4-styrenesulfonate)), NPB(N,N′-di(naphthalene-1-yl)-N,N′-diphenyl-benzidine), polyether ketone (TPAPEK) containing triphenylamine, 4-Isopropyl-4′-methyldiphenyliodonium[Tetrakis(pentafluorophenyl)borate], HATCN(dipyrazino [2,3-f: 2′, 3′-h] quinoxaline-2,3,6,7,10,11-hexacarbonitrile), etc.

Each of the hole transport regions HTR1, HTR2, HTR3, and HTR4 may include a carbazole-based derivative such as N-phenylcarbazole and polyvinylcarbazole, a fluorene-based derivative, TPD(N,N′-bis(3-methylphenyl)-N,N′-diphenyl-[1,1′-biphenyl]-4,4′-diamine), a triphenylamine-based derivative such as TCTA(4,4′,4″-tris(N-carbazolyl)triphenylamine), NPB(N,N′-di(naphthalene-1-yl)-N,N′-diplienyl-benzidine), TAPC(4,4′-Cyclohexylidene bis[N,N-bis(4-methylphenyl)benzenamine]), HMTPD(4,4′-Bis[N,N′-(3-tolyl)amino]-3,3′-dimethylbiphenyl), mCP(1,3-Bis(N-carbazolyl)benzene), etc.

In another embodiment, each of the hole transport regions HTR1, HTR2, HTR3, and HTR4 may include CzSi(9-(4-tert-Butylphenyl)-3,6-bis(triphenylsilyl)-9H-carbazole), CCP(9-phenyl-9H-3,9′-bicarbazole), mDCP(1,3-bis(1,8-dimethyl-9H-carbazol-9-yl)benzene), or the like.

In the hole transport regions HTR1, HTR2, HTR3, and HTR4, the compounds of the hole transport regions described above may be included in at least one of the hole injection layers HIL1, HIL2, HIL3, and HIL4, the hole transport layers HTL1, HTL2, HTL3, and HTL4, or the hole-side additional layer.

The thickness of each of the hole transport regions HTR1, HTR2, HTR3, and HTR4 may be in a range of about 10 nm to about 1000 nm. For example, the thickness of each of the hole transport regions HTR1, HTR2, HTR3, and HTR4 may be in a range of about 10 nm to about 500 nm. The thickness of each of the hole injection layers HIL1, HIL2, HIL3, and HIL4 may be, for example, in a range of about 5 nm to about 100 nm. The thickness of each of the hole transport layers HTL1, HTL2, HTL3, and HTL4 may be in a range of about 5 nm to about 100 nm. In case that the hole transport regions HTR1, HTR2, HTR3, and HTR4 include a hole-side additional layer, the thickness of the hole-side additional layer may be in a range of about 1 nm to about 100 nm. In case that the thickness of the hole transport regions HTR1, HTR2, HTR3, and HTR4 and the thickness of each layer included therein satisfy the above-mentioned ranges, satisfactory hole transport characteristics may be obtained without a substantial increase in driving voltage.

In addition to the materials mentioned above, each of the hole transport regions HTR1, HTR2, HTR3, and HTR4 may further include a charge generation material to improve conductivity. The charge generation material may be uniformly or non-uniformly dispersed in the hole transport regions HTR1, HTR2, HTR3, and HTR4. The charge generation material may be, for example, a p-type dopant. The p-type dopant may include at least one of a halogenated metal compound, a quinone derivative, a metal oxide, and a cyano group-containing compound, but the disclosure is not limited thereto. For example, the p-dopant may include a halogenated metal compound such as CuI and RbI, a quinone derivative such as TCNQ(Tetracyanoquinodimethane) and F4-TCNQ(2,3,5,6-tetrafluoro-7,7′8,8-tetracyanoquinodimethane), a metal oxide such as a tungsten oxide and a molybdenum oxide, and the like, but the disclosure is not limited thereto.

Each of the blue light-emitting layers BEML1, BEML2, and BEML3 and the green light-emitting layer GEML may include a host material and a dopant material. Each of the blue light-emitting layers BEML1, BEML2, and BEML3 and the green light-emitting layer GEML may include a material containing a carbazole derivative moiety or an amine derivative moiety as a hole transporting host material. Each of the blue light-emitting layers BEML1, BEML2, and BEML3 and the green light-emitting layer GEML may include a material having a nitrogen-containing aromatic ring structure, such as a pyridine derivative moiety, a pyridazine derivative moiety, a pyrimidine derivative moiety, a pyrazine derivative moiety, and a triazine derivative moiety, as an electron transporting host material.

Each of the blue light-emitting layers BEML1, BEML2, and BEML3 and the green light-emitting layer GEML may include an anthracene derivative, a pyrene derivative, a fluoranthene derivative, a chrysene derivative, a dihydrobenzo anthracene derivative, or a triphenylene derivative as a host material. In an embodiment, each of the blue light-emitting layer BEML1, BEML2, and BEML3 and the green light-emitting layer GEML may further include a general host material. For example, as a host material, each of the blue light-emitting layers BEML1, BEML2, and BEML3 and the green light-emitting layer GEML may include at least one of DPEPO(Bis[2-(diphenylphosphino)phenyl]ether oxide), CBP(4,4′-Bis(carbazol-9-yl)biphenyl), mCP(1,3-Bis(carbazol-9-yl)benzene), PPF(2,8-Bis(diphenylphosphoryl)dibenzo[b,d]furan), TCTA(4,4′,4″-Tris(carbazol-9-yl)-triphenylamine), and TPBi(1,3,5-tris(1-phenyl-1H-benzo[d]imidazole-2-yl)benzene). However, the disclosure is not limited thereto, and for example, Alq3 (tris(8-hydroxyquinolino)aluminum), PVK(poly(N-vinylcarbazole), ADN(9,10-di(naphthalene-2-yl)anthracene), TBADN(2-tert-butyl-9,10-di(naphth-2-yl)anthracene), DSA(distyrylarylene), CDBP(4,4′-bis(9-carbazolyl)-2,2′-dimethyl-biphenyl), MADN(2-Methyl-9,10-bis(naphthalen-2-yl)anthracene), CP1(Hexaphenyl cyclotriphosphazene), UGH2(1,4-Bis(triphenylsilyl)benzene), DPSiO3 (Hexaphenylcyclotrisiloxane), DPSiO4 (Octaphenylcyclotetra siloxane), and the like may be used as a host material.

In an embodiment of the disclosure, as a fluorescent dopant material, the blue light-emitting layers BEML1, BEML2, and BEML3 may include a styryl derivative (e.g., 1,4-bis[2-(3-N-ethylcarbazoryl)vinyl]benzene (BCzVB), 4-(di-p-tolylamino)-4′-[(di-p-tolylamino)styryl]stilbene(DPAVB), N-(4-((E)-2-(6-((E)-4-(diphenylamino)styryl) naphthalen-2-yl)vinyl)phenyl)-N-phenylbenzenamine (N-BDAVBi)), 4,4′-bis[2-(4-(N,N-diphenylamino)phenyl)vinyl]biphenyl(DPAVBi), perylene and its derivative (e.g., 2,5,8,11-Tetra-t-butylperylene (TBP)), pyrene and its derivative (e.g., 1,1-dipyrene, 1,4-dipyrenylbenzene, 1,4-Bis(N, N-Diphenylamino) pyrene), and the like.

The green light-emitting layer GEML may include a phosphorescent dopant material. For example, a metal complex containing iridium (Ir), platinum (Pt), osmium (Os), gold (Au), titanium (Ti), zirconium (Zr), hafnium (Hf), europium (Eu), terbium (Tb), or thulium (Tm) may be used as a phosphorescent dopant. Specifically, FIrpic (iridium (III) bis(4,6-difluorophenylpyridinato-N,C2′) picolinate), Fir6 (Bis(2,4-difluorophenylpyridinato)-tetrakis(1-pyrazolyl)borate iridium (III)), or PtOEP (platinum octaethyl porphyrin) may be used as a phosphorescent dopant.

Each of the electron transport regions ETR1, ETR2, ETR3, and ETR4 may have a single-layered structure made of a single material, a single-layered structure made of different materials, or a multi-layered structure having layers made of different materials. For example, at least some of the electron transport regions ETR1, ETR2, ETR3, and ETR4 may include an electron transport layer ETL4 and an electron injection layer EIL4.

Each of the electron transport regions ETR1, ETR2, ETR3, and ETR4 may be formed by using a method such as a vacuum deposition method, a spin coating method, a casting method, a Langmuir-Blodgett (LB) method, an inkjet printing method, a laser printing method, and a laser induced thermal imaging (LITI) method.

The electron transport regions ETR1, ETR2, ETR3, and ETR4 may include an anthracene-based compound. Without being limited thereto, however, each of the electron transport regions ETR1, ETR2, ETR3, and ETR4 may include, for example, Alq3 (Tris(8-hydroxyquinolinato)aluminum), 1,3,5-tri[(3-pyridyl)-phen-3-yl]benzene, T2T(2,4,6-tris(3′-(pyridin-3-yl)biphenyl-3-yl)-1,3,5-triazine), 2-(4-(N-phenylbenzoimidazol-1-yl)phenyl)-9,10-dinaphthylanthracene, TPBi(1,3,5-Tri (1-phenyl-1H-benzo[d]imidazol-2-yl)benzene), BCP(2,9-Dimethyl-4,7-diphenyl-1,10-phenanthroline), Bphen(4,7-Diphenyl-1,10-phenanthroline), TAZ(3-(4-Biphenylyl)-4-phenyl-5-tert-butylphenyl-1,2,4-triazole), NTAZ(4-(Naphthalen-1-yl)-3,5-diphenyl-4H-1,2,4-triazole), tBu-PBD(2-(4-Biphenylyl)-5-(4-tert-butylphenyl)-1,3,4-oxadiazole), BAlq(Bis(2-methyl-8-quinolinolato-N1,O8)-(1,1′-Biphenyl-4-olato)aluminum), Bebq2(berylliumbis(benzoquinolin-10-olate)), ADN(9,10-di(naphthalene-2-yl)anthracene), BmPyPhB(1,3-Bis[3,5-di(pyridin-3)-yl)phenyl]benzene) or a mixture thereof.

In an embodiment, each of the electron transport regions ETR1, ETR2, ETR3, and ETR4 may include a halogenated metal such as LiF, NaCl, CsF, RbCl, RbI, CuI, and KI, a lanthanide metal such as Yb, or a co-deposition material of the halogenated metal and the lanthanide metal. For example, the electron transport regions ETR1, ETR2, ETR3, and ETR4 may include KI:Yb, RbI:Yb, or the like as a co-deposited material. The electron transport region ETR1, ETR2, ETR3, and ETR4 may include at least one of Mg, Ag, Yb, and Al. For example, the electron transport regions ETR1, ETR2, ETR3, and ETR4 may include Mg and Yb.

In an embodiment, the electron transport regions ETR1, ETR2, ETR3, and ETR4 may include a metal oxide such as Li₂O and BaO, Liq (8-hydroxyl-Lithium quinolate), or the like, but the disclosure is not limited thereto. Each of the electron transport regions ETR1, ETR2, ETR3, and ETR4 may further include an electron transport material and an insulating organo metal salt. The organo metal salt may be a material having an energy band gap greater than or equal to about 4 eV. For example, the organo metal salt may include a metal acetate, a metal benzoate, a metal acetoacetate, a metal acetylacetonate, or a metal stearate.

Each of the electron transport regions ETR1, ETR2, ETR3, and ETR4 may further include at least one of BCP(2,9-dimethyl-4,7-diphenyl-1,10-phenanthroline) and Bphen(4,7-diphenyl-1,10-phenanthroline) in addition to the above-mentioned materials, but the disclosure is not limited thereto.

The electron transport regions ETR1, ETR2, ETR3, and ETR4 may include the compounds of the electron transport regions described above in the electron injection layer or the electron transport layer. In case that the electron transport regions ETR1, ETR2, ETR3, and ETR4 include an electron-side additional layer, the electron-side additional layer may include at least one of the above-described materials. In an embodiment of the disclosure, the electron injection layer EIL4 may include at least one of Mg, Ag, Yb, and Al. The electron injection layer EIL4 may include, for example, a mixture of Mg and Yb.

The thickness of each of the electron transport regions ETR1, ETR2, ETR3, and ETR4 may be, for example, in a range of about 10 nm to about 150 nm. The thickness of the electron transport layer may be in a range of about 0.1 nm to about 100 nm. For example, the thickness of the electron transport layer may be in a range of about 0.3 nm to about 50 nm. In case that the thickness of the electron transport layer satisfies the range described above, satisfactory electron transport characteristics may be obtained without a substantial increase in driving voltage.

The second electrode EL2 may be provided on the light-emitting stacks ST1, ST2, ST3, and ST4. The second electrode EL2 may be a common electrode. The second electrode EL2 may be a cathode or an anode, but the disclosure is not limited thereto. For example, in case that the first electrode EL1 is an anode, the second electrode EL2 may be a cathode, and in case that the first electrode EL1 is a cathode, the second electrode EL2 may be an anode.

The second electrode EL2 may be a semi-transmissive electrode or a transmissive electrode. In case that the second electrode EL2 is a transmissive electrode, the second electrode EL2 may include a transparent metal oxide such as indium tin oxide (ITO), indium zinc oxide (IZO), zinc oxide (ZnO), and indium tin zinc oxide (ITZO).

In case that the second electrode EL2 is a semi-transmissive electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, In, Zn, Sn, or a compound or mixture (e.g., AgMg, AgYb, or MgAg) thereof. In another embodiment, the second electrode EL2 may have a multi-layered structure including a reflective or semi-transmissive film formed of the above materials and a transparent conductive film formed of indium tin oxide (ITO), indium zinc oxide (IZO), zinc oxide (ZnO), indium tin zinc oxide (ITZO), or the like. For example, the second electrode EL2 may include an aforementioned metal material, a combination of two or more metal materials selected from among the aforementioned metal materials, an oxide of the aforementioned metal materials, or the like.

Although not illustrated, the second electrode EL2 may be connected to an auxiliary electrode. In case that the second electrode EL2 is connected to the auxiliary electrode, the resistance of the second electrode EL2 may be reduced.

In an embodiment, a capping layer CPL may be disposed on the second electrode EL2 of the light-emitting element LED according to an embodiment of the disclosure. The capping layer CPL may include multiple layers or a single layer.

In an embodiment of the disclosure, the capping layer CPL may be an organic layer or an inorganic layer. For example, in case that the capping layer CPL includes an inorganic material, the inorganic material may include an alkali metal compound such as LiF, an alkaline earth metal compound such as MgF₂, SiON, SiNₓ, SiO_{y}, etc.

For example, in case that the capping layer CPL includes an organic material, the organic material may include α-NPD, NPB, TPD, m-MTDATA, Alq3, CuPc, TPD15(N4,N4,N4′,N4′-tetra(biphenyl-4-yl)biphenyl-4,4′-diamine), TCTA (4,4′,4″-Tris (carbazol sol-9-yl)triphenylamine), or the like, or include an epoxy resin or acrylate such as methacrylate.

In an embodiment, the refractive index of the capping layer CPL may be greater than or equal to about 1.6. For example, the refractive index of the capping layer CPL may be greater than or equal to about 1.6 with respect to light in a wavelength range of about 550 nm to about 660 nm.

Referring again to FIG. 4A, in the light-emitting element LED according to an embodiment of the disclosure, the electron control layer ETR may be disposed between the light-emitting layer EML and the second electrode EL2. The electron control layer ETR may include at least one of an electron injection layer, an electron transport layer, and a hole blocking layer. Referring to FIG. 4A, the electron control layer ETR may be disposed as a common layer so as to entirely overlap the light-emitting regions EA1, EA2, and EA3 and the pixel defining film PDL that separates the light-emitting regions EA1, EA2, and EA3 in a plan view. However, the disclosure is not limited thereto, and in another embodiment, the electron control layer ETR may be patterned and provided so as to be separately disposed corresponding to each of the light-emitting regions EA1, EA2, and EA3.

The second electrode EL2 may be provided on the electron control layer ETR. The second electrode EL2 may be a common electrode. The second electrode EL2 may be a cathode or an anode, but the disclosure is not limited thereto. For example, in case that the first electrode EL1 is an anode, the second electrode EL2 may be a cathode, and in case that the first electrode EL1 is a cathode, the second electrode EL2 may be an anode. The second electrode EL2 may be a transmissive electrode, a semi-transmissive electrode, or a reflective electrode.

The encapsulation layer TFE may be disposed on the light-emitting element LED. For example, in an embodiment of the disclosure, the encapsulation layer TFE may be disposed on the second electrode EL2. In case that the light-emitting element LED includes a capping layer (not illustrated), the encapsulation layer TFE may be disposed on the capping layer (not illustrated). As described above, the encapsulation layer TFE may include at least one organic layer and at least one inorganic layer, and the inorganic layer and the organic layer may be alternately disposed.

The display panel DP according to an embodiment of the disclosure may include an optical structure layer OSL disposed on the display element layer DP-LED. The optical structure layer OSL may include a light control layer CCL, a color filter layer CFL, and a base layer BL.

The light control layer CCL may include a light converter. The light converter may be a quantum dot, a phosphor, or the like. The light converter may convert the wavelength of received light and emit the converted light. For example, the light control layer CCL may be a layer at least partially including a quantum dot or a phosphor.

The light control layer CCL may include multiple light control patterns CCP-R, CCP-G, and CCP-B. The light control patterns CCP-R, CCP-G, and CCP-B may be spaced apart from each other. The light control patterns CCP-R, CCP-G, and CCP-B may be spaced apart from each other by the bank BMP. The light control patterns CCP-R, CCP-G, and CCP-B may be disposed in bank openings BOH1, BOH2, and BOH3 defined in the bank BMP. However, the disclosure is not limited thereto. In FIG. 4A, the bank BMP is illustrated as having a rectangular shape and non-overlapping the light control patterns CCP-R, CCP-G, and CCP-B in a cross sectional view, but the disclosure is not limited thereto, and in another embodiment, the edges of some of the light control patterns CCP-R, CCP-G, and CCP-B may at least partially overlap the bank BMP. For example, the edge of a third light control pattern CCP-B may overlap the bank BMP in a plan view. The bank BMP may have a trapezoidal shape in a cross-sectional view. The bank BMP may have a shape in which the cross-sectional width of the bank BMP increases as the bank BMP approaches the display element layer DP-LED.

The light control patterns CCP-R, CCP-G, and CCP-B may convert the wavelength of light provided from the display element layer DP-LED or transmit the light provided.

The light control layer CCL may include a first light control pattern CCP-R that provides red light as a first light, a second light control pattern CCP-G that provides green light as a second light, and a third light control pattern CCP-B that provides blue light as a third light. The light control layer CCL may include a first light control pattern CCP-R that converts source light provided from the light-emitting element LED into a first light, a second light control pattern CCP-G that converts source light into a second light, and a third light control pattern CCP-B that transmits the source light. At least some of the light control patterns CCP-R, CCP-G, and CCP-B may include a quantum dot that converts source light into light of a specific wavelength.

Some of the light control patterns CCP-R, CCP-G, and CCP-B may be formed through an inkjet process. In an embodiment of the disclosure, the first light control pattern CCP-R and the second light control pattern CCP-G may be formed through an inkjet process. A liquid ink composition may be provided inside each of the first bank opening BOH1 and the second bank opening BOH2, and the provided ink composition may be polymerized through a thermal curing process or a light curing process to form the first light control pattern CCP-R and the second light control pattern CCP-G. The rest of the light control patterns CCP-R, CCP-G, and CCP-B may be formed through a photoresist process. In an embodiment of the disclosure, the third light control pattern CCP-B may be formed through a photoresist process. After a photoresist composition is provided in at least the third bank opening BOH3, the third light control pattern CCP-B may be formed by curing the provided photoresist composition. The light control layer CCL may further include a scatterer. The first light control pattern CCP-R may include a first quantum dot and a scatterer, the second light control pattern CCP-G may include a second quantum dot and a scatterer, and the third light control pattern CCP-B may not include a quantum dot, but may include a scatterer. Each of the first light control pattern CCP-R, the second light control pattern CCP-G, and the third light control pattern CCP-B may further include a base resin that disperses quantum dots and scatterers. As the third light control pattern CCP-B is formed through a photoresist process which will be described below, the third light control pattern CCP-B may include a photosensitive resin.

The light control layer CCL may include a first barrier layer CAP1 disposed on a side of the first light control pattern CCP-R. The light control layer CCL may include a first barrier layer CAP1 spaced apart from the display element layer DP-LED with the first light control pattern CCP-R interposed between the first barrier layer CAP1 and the display element layer DP-LED and a second barrier layer CAP2 adjacent to the display element layer DP-LED.

In the display panel DP, the optical structure layer OSL may include a color filter layer CFL disposed on the light control layer CCL. The color filter layer CFL may include color filters CF1, CF2, and CF3. The color filter layer CFL may include a first color filter CF1 configured to transmit a first light, a second color filter CF2 configured to transmit a second light, and a third color filter CF3 configured to transmit a source light. In an embodiment of the disclosure, the first color filter CF1 may be a red filter, the second color filter CF2 may be a green filter, and the third color filter CF3 may be a blue filter.

Each of the color filters CF1, CF2, and CF3 may include a polymer photosensitive resin and a colorant. The first color filter CF1 may include a red colorant, the second color filter CF2 may include a green colorant, and the third color filter CF3 may include a blue colorant. The first color filter CF1 may include a red pigment or a red dye, the second color filter CF2 may include a green pigment or a green dye, and the third color filter CF3 may include a blue pigment or a blue dye.

The first to third color filters CF1, CF2, and CF3 may be respectively disposed to correspond to the first pixel region PXA-R, the second pixel region PXA-G, and the third pixel region PXA-B. In an embodiment, the first to third color filters CF1, CF2, and CF3 may be respectively disposed to correspond to the first to third light control patterns CCP-R, CCP-G, and CCP-B.

In an embodiment, the color filters CF1, CF2, and CF3, which correspond to the peripheral regions NPXA disposed between the pixel regions PXA-R, PXA-G, and PXA-B and transmit different light, may overlap each other. The color filters CF1, CF2, and CF3 may overlap each other in the third direction DR3, which is the thickness direction, so as to demarcate boundaries between adjacent light-emitting regions PXA-R, PXA-G, and PXA-B. Unlike what is illustrated, in another embodiment, the color filter layer CFL may include a light blocking portion (not illustrated) to demarcate boundaries between adjacent color filters CF1, CF2, and CF3. The light blocking portion (not illustrated) may be formed of a blue filter, or may be formed by including an inorganic light blocking material or an organic light blocking material that includes a black pigment or a black dye.

The optical structure layer OSL may include a filling layer FML disposed between the light control layer CCL and the color filter layer CFL. The filling layer FML may be disposed between the light control patterns CCP-R, CCP-G, and CCP-B and the color filters CF1, CF2, and CF3. The filling layer FML may be disposed on the light control layer CCL to block the light control patterns CCP-R, CCP-G, and CCP-B from being exposed to moisture/oxygen. By being disposed between the light control patterns CCP-R, CCP-G, and CCP-B and the color filters CF1, CF2, and CF3, the filling layer FML may function as an optical functional layer to increase light extraction efficiency or prevent reflected light from being incident on the light control layer CCL. The filling layer FML may have a lower refractive index than other adjacent layers.

In an embodiment of the disclosure, the optical structure layer OSL may further include a base layer BL disposed on the color filter layer CFL. The base layer BL may be a member that provides a base surface on which a color filter layer CFL and a light control layer CCL are disposed. The base layer BL may be a glass substrate, a metal substrate, or a plastic substrate. However, the disclosure is not limited thereto, and the base layer BL may be an inorganic layer, an organic layer, or a composite material layer. Unlike what is illustrated, in another embodiment of the disclosure, the base layer BL may be omitted.

FIGS. 4B to 4D respectively illustrate display panels DP-1, DP-2, and DP-3 according to an embodiment of the disclosure, which are different from the display panel DP illustrated in FIG. 4A.

Referring to FIG. 4B, a display panel DP-1 according to an embodiment of the disclosure may include: a lower panel including a base substrate BS, a circuit element layer DP-CL disposed on the base substrate BS, and a display element layer DP-LED disposed on the circuit element layer DP-CL; and an optical structure layer OSL-1 disposed on the lower panel. The optical structure layer OSL-1 may include a light control layer CCL-1, a color filter layer CFL, and a base layer BL.

The display panel DP-1 according to an embodiment of the disclosure may include a lower panel including a display element layer DP-LED and an upper panel (optical structure layer, OSL-1) including a light control layer CCL-1 and a color filter layer CFL, and in an embodiment of the disclosure, a filling layer FML may be disposed between the lower panel and the upper panel OSL-1.

In an embodiment of the disclosure, the filling layer FML may fill a space between the display element layer DP-LED and the light control layer CCL-1. The filling layer FML may be disposed on (e.g., directly on) the encapsulation layer TFE, and the second barrier layer CAP2 may be disposed on (e.g., directly on) the filling layer FML. The lower surface of the filling layer FML may be in contact with the upper surface of the encapsulation layer TFE, and the upper surface of the filling layer FML may be in contact with the lower surface of the second barrier layer CAP2.

The filling layer FML may function as a buffer between the display element layer DP-LED and the light control layer CCL-1. In an embodiment of the disclosure, the filling layer FML may perform a shock absorbing function and the like and increase the strength of the display panel DP-1. The filling layer FML may be formed from a filling resin including a polymer resin. For example, the filling layer FML may be formed from a filling resin including an acrylic-based resin, an epoxy-based resin, or the like.

Compared to the display panel DP illustrated in FIG. 4A, the display panel DP-1 according to an embodiment of the disclosure, which is illustrated in FIG. 4B, is an embodiment in which the filling layer FML may be disposed between the display element layer DP-LED and the light control layer CCL-1. For example, in the display panel DP-1 of FIG. 4B, the circuit element layer DP-CL and the display element layer DP-LED, as a lower panel, may be disposed on the upper surface of the base substrate BS used as a base surface, and the color filter layer CFL and the light control layer CCL-1, as an upper panel (optical structure layer, OSL-1), may be disposed on the upper surface of the base layer BL used as a base surface, and the display panel DP-1 may be formed by coupling the lower panel and the upper panel to each other with the filling layer FML interposed between the lower panel and the upper panel.

In the display panel DP-1 according to an embodiment of the disclosure, a step may be formed between the lower surface of the bank BMP and the lower surface of the light control patterns CCP-R, CCP-G, and CCP-B. For example, the lower surface of the bank BMP may be defined to be higher than the lower surface of the light control patterns CCP-R, CCP-G, and CCP-B. The height difference between the lower surface of the bank BMP and the lower surface of the light control patterns CCP-R, CCP-G, and CCP-B may be, for example, in a range of about 2 μm to about 3 μm.

The second barrier layer CAP2 may be disposed to follow the step between the bank BMP and the light control patterns CCP-R, CCP-G, and CCP-B. The second barrier layer CAP2 may be disposed on (e.g., directly on) the filling layer FML.

The display panel DP-1 according to an embodiment of the disclosure may include a low refractive layer LR. The low refractive layer LR may be disposed between the light control layer CCL-1 and the color filter layer CFL. The low refractive layer LR may be disposed above the light control layer CCL to block the light control patterns CCP-R, CCP-G, and CCP-B from being exposed to moisture/oxygen. By being disposed between the light control patterns CCP-R, CCP-G, and CCP-B and the color filters CF1, CF2, and CF3, the low refractive layer LR may also function as an optical functional layer to increase light extraction efficiency or prevent reflected light from being incident on the light control layer CCL. The low refractive layer LR may have a lower refractive index than adjacent layers.

The low refractive layer LR may include at least one inorganic layer. For example, the low refractive layer LR may include silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, a metal thin film having a secured light transmittance, or the like. However, the disclosure is not limited thereto, and the low refractive layer LR may include an organic film. For example, the low refractive layer LR may have a structure in which multiple hollow particles are dispersed in an organic polymer resin. The low refractive layer LR may be composed of a single layer or multiple layers.

Referring to FIG. 4C, a display panel DP-2 according to an embodiment of the disclosure may include: a lower panel including a base substrate BS, a circuit element layer DP-CL disposed on the base substrate BS, and a display element layer DP-LED disposed on the circuit element layer DP-CL; and an optical structure layer OSL-2 disposed on the lower panel. In the display panel DP-2 according to an embodiment of the disclosure, the optical structure layer OSL-2 may include a light control layer CCL, a low refractive layer LR-1, a color filter layer CFL-1, and a base layer BL-1 which are sequentially stacked on a thin film encapsulation layer TFE. The optical structure layer OSL-2 may include a first barrier layer CAP1 and a second barrier layer CAP2 which are disposed on the upper and lower surfaces of the light control layer CCL.

The light control layer CCL may be disposed on the display element layer DP-LED and the thin film encapsulation layer TFE with the second barrier layer CAP2 interposed between the thin film encapsulation layer TFE and the light control layer CCL. The light control layer CCL may include multiple banks BMP and light control patterns CCP-R, CCP-G, and CCP-B disposed between the banks BMP. The low refractive layer LR-1 may be disposed on the light control layer CCL.

The color filter layer CFL-1 may include multiple color filters CF1, CF2, and CF3 and a light blocking portion BM.

Compared to the display panel DP-1 illustrated in FIG. 4B, the display panel DP-2 according to an embodiment of the disclosure, which are illustrated in FIG. 4C, is an embodiment in which the light control layer CCL, the low refractive layer LR-1, and the color filter layer CFL-1 may be disposed on the upper surface of the thin film encapsulation layer TFE used as a base surface. For example, the light control patterns CCP-R, CCP-G, and CCP-B of the light control layer CCL may be formed on the thin film encapsulation layer TFE in a continuous process, and the color filters CF1, CF2, and CF3 of the color filter layer CFL-1 may be sequentially formed on the light control layer CCL through a continuous process. The light control layer CCL may be formed on the upper surface of the second barrier layer CAP2, which is disposed on the thin film encapsulation layer TFE and used as a base surface, and may have a shape that is inverted vertically compared to the shape of the light control layer CCL illustrated in FIG. 4B. For example, each of the banks BMP and the light control patterns CCP-R, CCP-G, and CCP-B may have a shape that is inverted vertically compared to what is illustrated in FIG. 4B. The color filter layer CFL-1 may be formed on the upper surface of the light control layer CCL used as a base surface and may have a shape different from what is illustrated in FIGS. 4A and 4B.

In the color filter layer CFL-1 according to an embodiment of the disclosure, the light blocking portion BM may be a black matrix. The light blocking portion BM may be formed of an inorganic light blocking material or an organic light blocking material including a black pigment or a black dye. The light blocking portion BM may prevent light leakage and demarcate boundaries between adjacent color filters CF1, CF2, and CF3.

Referring to FIG. 4D, a display element layer DP-LED1 included in a display panel DP-3 according to an embodiment of the disclosure may include a light-emitting element LED-1, and the light-emitting element LED-1 may be a micro LED element or a nano LED element. The light-emitting element LED-1 may be disposed between the pixel defining films PDL and may be electrically connected to a contact portion S-C, and the length and width of the light-emitting element LED-1 may be about hundreds of nanometers to about hundreds of micrometers. The light-emitting element LED-1 may be an LED element including an active layer and at least one semiconductor material layer. The light-emitting element LED-1 may further include an insulating layer covering the surfaces of the active layer and the semiconductor material layer. The light-emitting element LED-1 may be patterned and overlap each of the light-emitting regions PXA-R, PXA-B, and PXA-G in a plan view. The display panel DP-3 may include a buffer layer BFL disposed on the light-emitting element LED-1. The buffer layer BFL may be disposed on and cover the light-emitting element LED-1. In another embodiment, in the display panel DP-3, which is illustrated in FIG. 4D, the buffer layer BFL may be omitted.

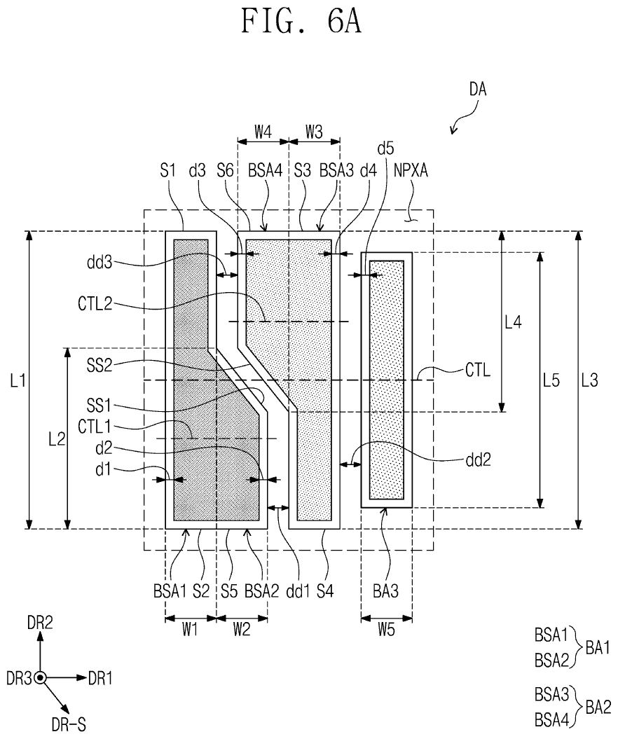

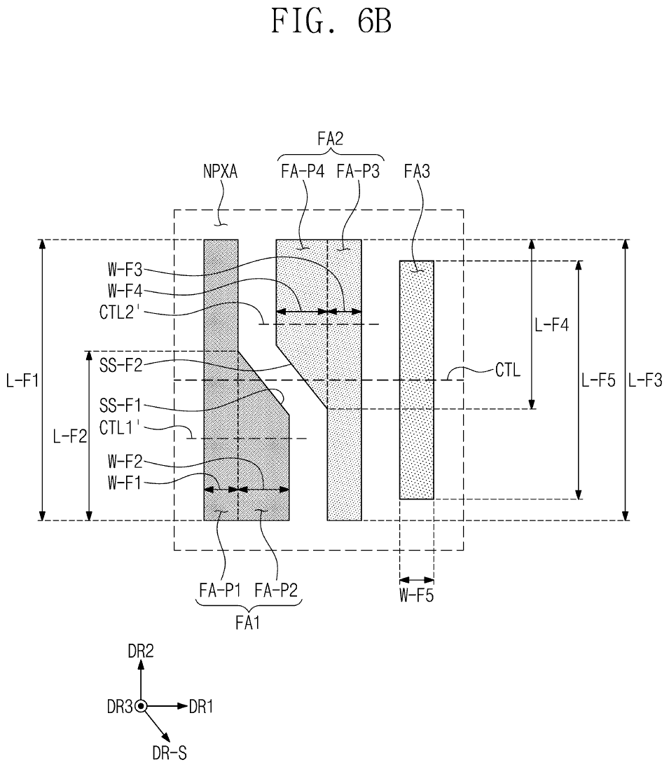

FIG. 6A is an enlarged plan view of a portion of a display panel according to an embodiment of the disclosure. FIG. 6B is an enlarged plan view of some of the components of the display panel according to an embodiment of the disclosure. Among the display region DA illustrated in FIG. 2, FIG. 6A schematically illustrates the arrangement and shape of filter regions FA1, FA2, and FA3 and bank openings BOH1, BOH2, and BOH3 in a plan view corresponding to one first filter region FA1, one second filter region FA2, and one third filter region FA3. In a view corresponding to FIG. 6A, FIG. 6B schematically illustrates the planar shape of the filter regions FA1, FA2, and FA3 in a plan view corresponding to one first filter region FA1, one second filter region FA2, and one third filter region FA3.

Referring to FIGS. 2, 3, 4A, and 6A together, the first to third filter regions FA1, FA2, and FA3 may respectively correspond to the above-described first to third pixel regions PXA-R, PXA-G, and PXA-B and may be defined by the color filters CF1, CF2, and CF3. The first filter region FA1 may be defined by the first color filter CF1, the second filter region FA2 may be defined by the second color filter CF2, and the third filter region FA3 may be defined by the third color filter CF3. The first filter region FA1 may overlap the first color filter CF1 and may not overlap the second color filter CF2 and the third color filter CF3 in a plan view. The second filter region FA2 may overlap the second color filter CF2 and may not overlap the first color filter CF1 and the third color filter CF3 in a plan view. The third filter region FA3 may overlap the third color filter CF3 and may not overlap the first color filter CF1 and the second color filter CF2 in a plan view.

The bank opening defined in the bank BMP may include a first bank opening BOH1, a second bank opening BOH2, and a third bank opening BOH3. A first light control pattern CCP-R may be disposed in the first bank opening BOH1, a second light control pattern CCP-G may be disposed in the second bank opening BOH2, and a third light control pattern CCP-B may be disposed in the third bank opening BOH3. In this specification, a region defined by the first bank opening BOH1 may be described as a first bank region BA1, a region defined by the second bank opening BOH2 may be described as a second bank region BA2, and a region defined by the third bank opening BOH3 may be described as a third bank region BA3.

In an embodiment of the disclosure, the first bank region BA1 may include a first sub-region BSA1 and a second sub-region BSA2. The first sub-region BSA1 and the second sub-region BSA2 may have an integral shape and may be connected to each other. The first light control pattern CCP-R may be disposed in the first bank opening BOH1 defining the first sub-region BSA1 and the second sub-region BSA2. For example, the first light control pattern CCP-R may overlap both the first sub-region BSA1 and the second sub-region BSA2 in a plan view.

The first sub-region BSA1 may have a rectangular shape with long sides extending in the second direction DR2 in a plan view. The second sub-region BSA2 may have a shape that protrudes from the first sub-region BSA1 in the first direction DR1. In an embodiment of the disclosure, the second sub-region BSA2 may have a shape that protrudes in the first direction DR1 from a portion of a long side of the first sub-region BSA1 having a rectangular shape.

The second sub-region BSA2 may be shorter in the second direction DR2 than the first sub-region BSA1. The first sub-region BSA1 may have a first length L1 in the second direction DR2, the second sub-region BSA2 may have a second length L2 in the second direction DR2, and the second length L2 may be less than the first length L1.

In an embodiment of the disclosure, the second bank region BA2 may include a third sub-region BSA3 and a fourth sub-region BSA4. The third sub-region BSA3 and the fourth sub-region BSA4 may have an integral shape and may be connected to each other. The second light control pattern CCP-G may be disposed in the second bank opening BOH2 defining the third sub-region BSA3 and the fourth sub-region BSA4. For example, the second light control pattern CCP-G may overlap both the third sub-region BSA3 and the fourth sub-region BSA4 in a plan view.

The third sub-region BSA3 may have a rectangular shape with long sides extending in the second direction DR2 in a plan view. The fourth sub-region BSA4 has a shape that protrudes from the third sub-region BSA3 in a direction opposite to the first direction DR1. In an embodiment of the disclosure, the fourth sub-region BSA4 may have a shape that protrudes in a direction opposite to the first direction DR1 from a portion of a long side of the third sub-region BSA3 having a rectangular shape.

The length of the fourth sub-region BSA4 in the second direction DR2 may be less than the length of the third sub-region BSA3. The third sub-region BSA3 may have a third length L3 in the second direction DR2, the fourth sub-region BSA4 may have a fourth length L4 in the second direction DR2, and the fourth length L4 may be less than the third length L3.

The second sub-region BSA2 and the fourth sub-region BSA4 may respectively include hypotenuses SS1 and SS2 extending in a diagonal direction DR-S forming an acute angle with the first direction DR1. The second sub-region BSA2 may include a first hypotenuse SS1 extending in the diagonal direction DR-S, and the fourth sub-region BSA4 may include a second hypotenuse SS2 extending in the diagonal direction DR-S. The first hypotenuse SS1 and the second hypotenuse SS2 may be parallel to each other and may face each other in a plan view.

Each of the second sub-region BSA2 and the fourth sub-region BSA4 may protrude in a staggered form from the upper or lower portion of each of a long side of the first sub-region BSA1 and the third sub-region BSA3. As illustrated in FIG. 6A, in case that the second sub-region BSA2 has a shape that protrudes from the lower portion of a long side of the first sub-region BSA1 in the first direction DR1, the fourth sub-region BSA4 may have a shape that protrudes from the upper portion of a long side of the third sub-region BSA3 in a direction opposite to the first direction DR1. In another embodiment, unlike what is illustrated, in case that the second sub-region BSA2 has a shape that protrudes from the upper portion of a long side of the first sub-region BSA1 in the first direction DR1, the fourth sub-region BSA4 may have a shape that protrudes from the lower portion of a long side of the third sub-region BSA3 in a direction opposite to the first direction DR1.

The first sub-region BSA1 may include two short sides spaced apart from each other in the second direction DR2. The first sub-region BSA1 may include a first side S1 and a second side S2 extending in the first direction DR1 and spaced apart from each other in the second direction DR2.

The third sub-region BSA3 may include two short sides spaced apart from each other in the second direction DR2. The third sub-region BSA3 may include a third side S3 and a fourth side S4 extending in the first direction DR1 and spaced apart from each other in the second direction DR2. The first side S1 of the first sub-region BSA1 and the third side S3 of the third sub-region BSA3 may be colinear with each other in the first direction DR1. The second side S2 of the first sub-region BSA1 and the fourth side S4 of the third sub-region BSA3 may be colinear with each other in the first direction DR1.

The second sub-region BSA2 may have a shape that protrudes from the lower portion of a long side of the first sub-region BSA1 in the first direction DR1, and the lower side of the second sub-region BSA2 and the lower side of the first sub-region BSA1 may be aligned with each other. The second sub-region BSA2 may include a fifth side S5 extending in the first direction DR1, and the fifth side S5 may be aligned with the second side S2. The fifth side S5 may be aligned with the second side S2 to define a side extending in the first direction DR1. In another embodiment, unlike what is illustrated in FIG. 6A, in case that the second sub-region BSA2 has a shape that protrudes from the upper portion of a side of the first sub-region BSA1 in the first direction DR1, the fifth side S5 may be aligned with the first side S1.

The fourth sub-region BSA4 may have a shape that protrudes from the upper portion of a long side of the third sub-region BSA3 in a direction opposite to the first direction DR1, and the upper side of the fourth sub-region BSA4 and the upper side of the third sub-region BSA3 may be aligned with each other. The fourth sub-region BSA4 may include a sixth side S6 extending in the first direction DR1, and the sixth side S6 may be aligned with the third side S3. The sixth side S6 may be aligned with the third side S3 to define a side extending in the first direction DR1. In another embodiment, unlike what is illustrated in FIG. 6A, in case that the fourth sub-region BSA4 has a shape that protrudes from the lower portion of a long side of the third sub-region BSA3 in a direction opposite to the first direction DR1, the sixth side S6 may be aligned with the fourth side S4.

The first bank region BA1 and the second bank region BA2 may have a shape similar to each other in a plan view. As illustrated in FIG. 6A, the second bank region BA2 may have a shape obtained by rotating the first bank region BA1 by 180 degrees. The first length L1 of the first sub-region BSA1 and the third length L3 of the third sub-region BSA3 may be substantially the same as each other. The second length L2 of the second sub-region BSA2 and the fourth length L4 of the fourth sub-region BSA4 may be substantially the same as each other. In this specification, being “substantially the same” may include not only a case in which lengths, widths, areas, or the like are physically the same as each other, but also a case in which there is a difference equal to a process error that occurs despite a same design.

The first sub-region BSA1 may have a first width W1 in the first direction DR1, and the second sub-region BSA2 may have a second width W2 in the first direction DR1. The third sub-region BSA3 may have a third width W3 in the first direction DR1, and the fourth sub-region BSA4 may have a fourth width W4 in the first direction DR1. In an embodiment of the disclosure, the first width W1 and the third width W3 may be substantially the same. The second width W2 and the fourth width W4 may be substantially the same. The second width W2 may be smaller than the first width W1, and the fourth width W4 may be smaller than the third width W3. Each of the first width W1 and the third width W3 may be in a range of about 30 micrometers to about 40 micrometers. Each of the second width W2 and the fourth width W4 may be in a range of about 10 micrometers to about 20 micrometers. The combined width of the first width W1 and the second width W2, for example, the width of the first bank region BA1 in the first direction DR1 may be in a range of about 40 micrometers to about 60 micrometers. The combined width of the third width W3 and the fourth width W4, for example, the width of the second bank region BA2 in the first direction DR1 may be in a range of about 40 micrometers to about 60 micrometers.

In an embodiment of the disclosure, the third bank region BA3 may have a fifth width W5 in the first direction DR1 and a fifth length L5 in the second direction DR2. The third bank region BA3 may have a rectangular shape in a plan view.

The fifth width W5 and the first width W1 of the first sub-region BSA1 may be substantially the same. The fifth width W5 and the third width W3 of the third sub-region BSA3 may be substantially the same. For example, the widths of the first sub-region BSA1, the third sub-region BSA3, and the third bank region BA3 in the first direction DR1 may be constant.

The fifth length L5 may be less than the first length L1 of the first sub-region BSA1 and the third length L3 of the third sub-region BSA3. For example, the third bank region BA3 may have a smaller length than each of the first sub-region BSA1 and the third sub-region BSA3 in the second direction DR2. The third bank region BA3 may have a smaller length than each of the first bank region BA1 and the second bank region BA2 in the second direction DR2.

Each of the first to third filter regions FA1, FA2, and FA3 may have a polygonal shape in a plan view. Each of the first to third filter regions FA1, FA2, and FA3 may have a polygonal shape similar to a corresponding region among the first to third bank regions BA1, BA2, and BA3. The areas of the first to third filter regions FA1, FA2, and FA3 may be set according to the colors of emitted light. The area of the first filter region FA1 that emits red light and the area of the second filter region FA2 that emits green light may be substantially the same as each other, and the area of the third filter region FA3 that emits blue light may be smaller than the area of the first filter region FA1 and the area of the second filter region FA2.

The first filter region FA1 may include a first sub-filter region FA-P1 and a second sub-filter region FA-P2. The first sub-filter region FA-P1 may overlap the first sub-region BSA1 of the first bank region BA1 in a plan view. The first sub-filter region FA-P1 may have a rectangular shape with long sides extending in the second direction DR2 in a plan view. The second sub-filter region FA-P2 may have a shape that protrudes from a portion of a long side of the first sub-filter region FA-P1 in the first direction DR1. At least a portion of the second sub-filter region FA-P2 may overlap the second sub-region BSA2 of the first bank region BA1 in a plan view.

The second filter region FA2 may include a third sub-filter region FA-P3 and a fourth sub-filter region FA-P4. The third sub-filter region FA-P3 may overlap the third sub-region BSA3 of the second bank region BA2 in a plan view. The third sub-filter region FA-P3 may have a rectangular shape with long sides extending in the second direction DR2 in a plan view. The fourth sub-filter region FA-P4 may have a shape that protrudes from a portion of a long side of the third sub-filter region FA-P3 in a direction opposite to the first direction DR1. At least a portion of the fourth sub-filter region FA-P4 may overlap the fourth sub-region BSA4 of the second bank region BA2 in a plan view.

The second sub-filter region FA-P2 and the fourth sub-filter region FA-P4 may respectively include hypotenuses SS-F1 and SS-F2 extending in the diagonal direction DR-S forming an acute angle with the first direction DR1. The second sub-filter region FA-P2 may include a first filter hypotenuse SS-F1 extending in the diagonal direction DR-S, and the fourth sub-filter region FA-P4 may include a second filter hypotenuse SS-F2 extending in the diagonal direction DR-S. The first filter hypotenuse SS-F1 and the second filter hypotenuse SS-F2 may be parallel to each other and may face each other in a plan view.

Each of the second sub-filter region FA-P2 and the fourth sub-filter region FA-P4 may protrude in a staggered form from the upper or lower portion of each of a long side of the first sub-filter region FA-P1 and the third sub-filter region FA-P3. As illustrated in FIG. 6B, in case that the second sub-filter region FA-P2 has a shape that protrudes from the lower portion of a long side of the first sub-filter region FA-P1 in the first direction DR1, the fourth sub-filter region FA-P4 may have a shape that protrudes from the upper portion of a long side of the third sub-filter region FA-P3 in a direction opposite to the first direction DR1. In another embodiment, unlike what is illustrated, in case that the second sub-filter region FA-P2 has a shape that protrudes from the upper portion of a long side of the first sub-filter region FA-P1 in the first direction DR1, the fourth sub-filter region FA-P4 may have a shape that protrudes from the lower portion of a long side of the third sub-filter region FA-P3 in a direction opposite to the first direction DR1.

The first filter region FA1 and the second filter region FA2 may have a shape similar to each other in a plan view. As illustrated in FIG. 6B, the second filter region FA2 may have a shape obtained by rotating the first filter region FA1 by 180 degrees. A first filter length L-F1 of the first sub-filter region FA-P1 and a third filter length L-F3 of the third sub-filter region FA-P3 may be substantially the same as each other in the second direction DR2. A second filter length L-F2 of the second sub-filter region FA-P2 and a fourth filter length L-F4 of the fourth sub-filter region FA-P4 may be substantially the same as each other in the second direction DR2.

The first sub-filter region FA-P1 may have a first filter width W-F1 in the first direction DR1, and the second sub-filter region FA-P2 may have a second filter width W-F2 in the first direction DR1. The third sub-filter region FA-P3 may have a third filter width W-F3 in the first direction DR1, and the fourth sub-filter region FA-P4 may have a fourth filter width W-F4 in the first direction DR1. In an embodiment of the disclosure, the first filter width W-F1 and the third filter width W-F3 may be substantially the same. The second filter width W-F2 and the fourth filter width W-F4 may be substantially the same.

In an embodiment of the disclosure, the third filter region FA3 may have a fifth filter width W-F5 in the first direction DR1 and a fifth filter length L-F5 in the second direction DR2. The third filter region FA3 may have a rectangular shape in a plan view.

The fifth filter width W-F5 and the first filter width W-FI of the first sub-filter region FA-P1 may be substantially the same. The fifth filter width W-F5 and the third filter width W-F3 of the third sub-filter region FA-P3 may be substantially the same. For example, the widths of the first sub-filter region FA-P1, the third sub-filter region FA-P3, and the third filter region FA3 in the first direction DR1 may be constant.

The fifth filter length L-F5 may be smaller than the first filter length L-FI of the first sub-filter region FA-P1 and the third filter length L-F3 of the third sub-filter region FA-P3. For example, the third filter region FA3 may have a smaller length than each of the first sub-filter region FA-P1 and the third sub-filter region FA-P3 in the second direction DR2. The third filter region FA3 may have a smaller length than each of the first filter region FA1 and the second filter region FA2 in the second direction DR2.

In an embodiment of the disclosure, in the first to third bank regions BA1, BA2, and BA3 and the first to third filter regions FA1, FA2, and FA3 corresponding to the first to third bank regions BA1, BA2, and BA3, the separation distances between the first to third bank regions BA1, BA2, and BA3 and the first to third filter regions FA1, FA2, and FA3 may be constant in a plan view. The separation distance between the first bank region BA1 and the first filter region FA1, the separation distance between the second bank region BA2 and the second filter region FA2, and the separation distance between the third bank region BA3 and the third filter regions FA3 may be constant. The expression “the separation distance between a region A and a region B” may mean the minimum distance from one point of the region A to one point of the region B that is closest to the point of the region A in a plan view. A first separation distance d1 between the first sub-region BSA1 and the first filter region FA1 and a second separation distance d2 between the second sub-region BSA2 and the first filter region FA1 may be substantially the same. A third separation distance d3 between the third sub-region BSA3 and the second filter region FA2 and a fourth separation distance d4 between the fourth sub-region BSA4 and the second filter region FA2 may be substantially the same. A fifth separation distance d5 between the third bank region BA3 and the third filter region FA3 and each of the first to fourth separation distances d4 described above may be substantially the same. In an embodiment of the disclosure, the first to fifth separation distances d1, d2, d3, d4, and d5 may be constant.

In an embodiment of the disclosure, the first bank region BA1, the second bank region BA2, and the third bank region BA3 may be sequentially arranged in the first direction DR1. In an embodiment, the separation distances between the first bank region BA1, the second bank region BA2, and the third bank region BA3 in the first direction DR1 may be constant. In an embodiment of the disclosure, a first separation distance dd1 between the second sub-region BSA2 and the fourth sub-region BSA4 adjacent to each other and a second separation distance dd2 between the fourth sub-region BSA4 and the third bank region BA3 adjacent to each other may be substantially the same as each other. The first separation distance dd1 between the second sub-region BSA2 and the fourth sub-region BSA4 and a third separation distance dd3 between the first sub-region BSA1 and the third sub-region BSA3 may be substantially the same as each other. Each of the first separation distance dd1, the second separation distance dd2, and the third separation distance dd3 may be in a range of about 8 micrometers to about 13 micrometers.

In an embodiment of the disclosure, the center lines CTL of the first sub-region BSA1, the third sub-region BSA3, and the third bank region BA3 in the second direction DR2 may be aligned with each other. In this specification, the center line in the second direction DR2 may correspond to an imaginary line extending in the first direction DR1 and passing the midpoint between an end and another end of each region in the second direction DR2. The center lines CTL of the first bank region BA1, the second bank region BA2, and the third bank region BA3 in the second direction DR2 may be aligned with each other. The center lines CTL of the first filter region FA1, the second filter region FA2, and the third filter region FA3 in the second direction DR2 may be aligned with each other. The center lines CTL of the first sub-filter region FA-P1, the third sub-filter region FA-P3, and the third bank region BA3 in the second direction DR2 may be aligned with each other.

As the second sub-region BSA2 and the fourth sub-region BSA4 respectively protruding from the first sub-region BSA1 and the third sub-region BSA3 are disposed in a staggered form, the center lines in the second direction DR2 may be not aligned with each other and may not overlap each other. A center line CTL1 of the second sub-region BSA2 in the second direction DR2 and a center line CTL2 of the fourth sub-region BSA4 in the second direction DR2 may be not aligned with each other and may not overlap each other in the first direction DR1. Similarly, a center line CTL1′ of the second sub-filter region FA-P2 in the second direction DR2 and a center line CTL2′ of the fourth sub-filter region FA-P4 in the second direction DR2 may be not aligned with each other and may not overlap each other in the first direction DR1.

In the display panel according to an embodiment of the disclosure, the first bank region BA1 defined by the first bank opening BOH1 in which the first light control pattern CCP-R is disposed may include a first sub-region BSA1 and a second sub-region BSA2 protruding from the first sub-region BSA1 in the first direction DR1. In an embodiment, the second bank region BA2 defined by the second bank opening BOH2 in which the second light control pattern CCP-G is disposed may include a third sub-region BSA3 and a fourth sub-region BSA4 protruding from the third sub-region BSA3 in a direction opposite to the first direction DR1. In the display panel according to an embodiment of the disclosure, as the sizes of pixel regions are reduced, high resolution may be achieved. It may be possible to secure a wide inkjet process impact region since each of the second sub-region BSA2 and the fourth sub-region BSA4 having a protruding structure may provide a wide width in the first direction DR1, thus the efficiency of the process forming the first light control pattern and the second light control pattern may be improved.

In the display panel DP according to an embodiment of the disclosure, the third bank region BA3 defined by the third bank opening BOH3 in which the third light control pattern CCP-B is disposed is defined, and the center lines CTL of the first sub-region BSA1, the third sub-region BSA3, and the third bank region BA3 in the second direction DR2 may be aligned with each other. In the display panel DP according to an embodiment of the disclosure, each of the second sub-region BSA2 and the fourth sub-region BSA4 may protrude in a staggered form from the upper portion or lower portion of each of a long side of the first sub-region BSA1 and the third sub-region BSA3. Therefore, it may be possible to secure a region in which the third bank region BA3 is disposed, and the center lines CTL of the first sub-region BSA1, the third sub-region BSA3, and the third bank region BA3 may be aligned with each other. Accordingly, in case that pixel regions are provided in an unaligned state, it may be possible to prevent a color fringing phenomenon in which the colors of other pixels are provided in the form of an outline at the edge portions of some pixels, thus improving the display quality of the display panel.

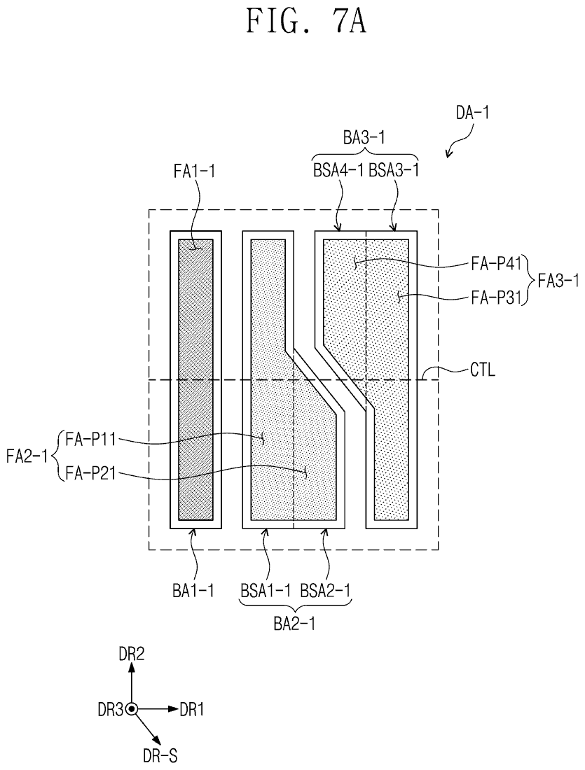

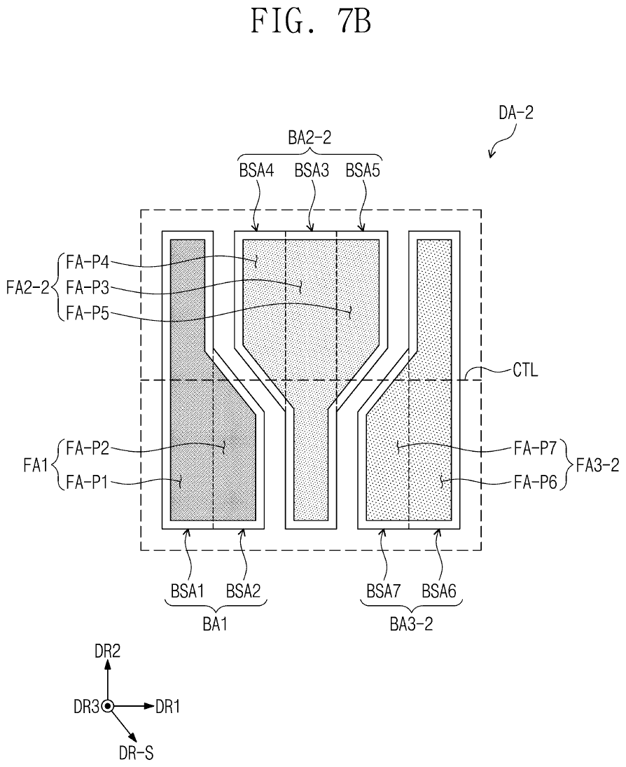

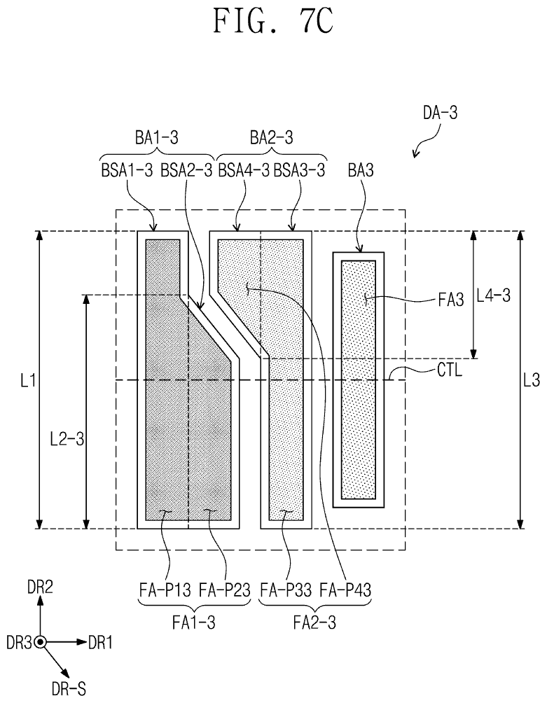

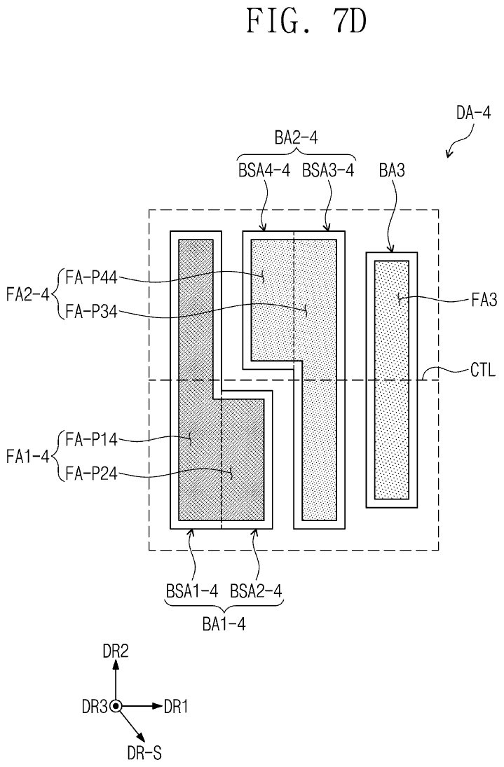

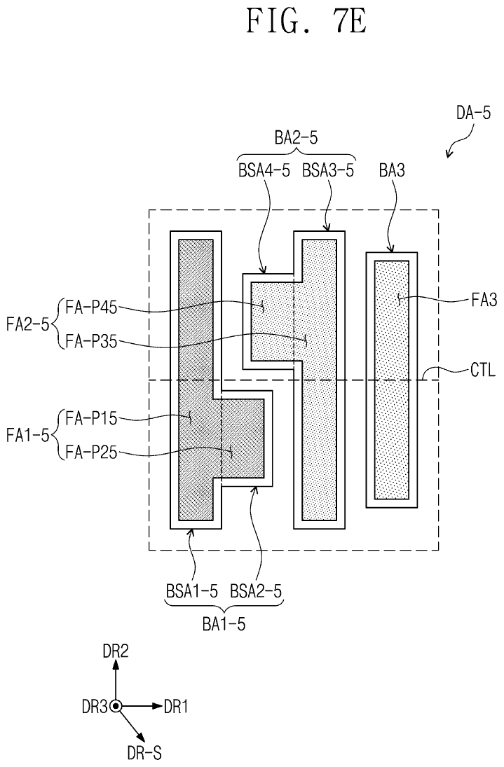

Each of FIGS. 7A to 7E is an enlarged plan view of a portion of a display panel according to an embodiment of the disclosure. FIGS. 7A to 7E schematically illustrate the arrangement relationships of multiple filter regions and bank regions in display regions DA-1, DA-2, DA-3, DA-4, and DA-5 according to another embodiment of the disclosure, which are different from the display region DA illustrated in FIG. 6A.

Referring to FIG. 7A, in a display region DA-1 according to an embodiment of the disclosure, sub-regions protruding in a staggered form may be included in a second bank region BA2-1 and a third bank region BA3-1 unlike the display region DA illustrated in FIG. 6A and in which the sub-regions are included in the first bank region BA1 and the second bank region BA2. For example, in the display region DA of FIG. 6A, the first bank region BA1 may include the first sub-region BSA1 and the second sub-region BSA2, and the second bank region BA2 may include the third sub-region BSA3 and the fourth sub-region BSA4, but in the display region DA-1 according to an embodiment of the disclosure, which is illustrated in FIG. 7A, the second bank region BA2-1 may include a first sub-region BSA1-1 and a second sub-region BSA2-1, and the third bank region BA3-1 may include a third sub-region BSA3-1 and a fourth sub-region BSA4-1.

The first sub-region BSA1-1 may have a rectangular shape with long sides extending in the second direction DR2 in a plan view. The second sub-region BSA2-1 may have a shape that protrudes from the first sub-region BSA1-1 in the first direction DR1. In an embodiment of the disclosure, the second sub-region BSA2-1 may have a shape that protrudes in the first direction DR1 from a portion of a long side of the first sub-region BSA1-1 having a rectangular shape. The third sub-region BSA3-1 may have a rectangular shape with long sides extending in the second direction DR2 in a plan view. The fourth sub-region BSA4-1 may have a shape that protrudes from the third sub-region BSA3-1 in a direction opposite to the first direction DR1. In an embodiment of the disclosure, the fourth sub-region BSA4-1 may have a shape that protrudes in a direction opposite to the first direction DR1 from a portion of a long side of the third sub-region BSA3-1 having a rectangular shape.

In the display region DA-1 according to an embodiment of the disclosure, which is illustrated in FIG. 7A, the second filter region FA2-1 may include a first sub-filter region FA-P11 and a second sub-filter region FA-P21. The first sub-filter region FA-P11 may overlap the first sub-region BSA1-1 of the second bank region BA2-1 in a plan view. The first sub-filter region FA-P11 may have a rectangular shape with long sides extending in the second direction DR2 in a plan view. The second sub-filter region FA-P21 may have a shape that protrudes in the first direction DR1 from a portion of a long side of the first sub-filter region FA-P11. At least a portion of the second sub-filter region FA-P21 may overlap the second sub-region BSA2-1 of the second bank region BA2 in a plan view. The third filter region FA3-1 may include a third sub-filter region FA-P31 and a fourth sub-filter region FA-P41. The third sub-filter region FA-P31 may overlap the third sub-region BSA3-1 of the third bank region BA3-1 in a plan view. The third sub-filter region FA-P31 may have a rectangular shape with long sides extending in the second direction DR2 in a plan view. The fourth sub-filter region FA-P41 may have a shape that protrudes in a direction opposite to the first direction DR1 from a portion of a long side of the third sub-filter region FA-P31. At least a portion of the fourth sub-filter region FA-P41 may overlap the fourth sub-region BSA4-1 of the third bank region BA3-1 in a plan view.

In the display region DA-1 according to an embodiment of the disclosure, the first bank region BA1-1 may have a rectangular shape in a plan view. The first filter region FA1-1 may have a rectangular shape in a plan view.

Referring to FIG. 7B, in a display region DA-2 according to an embodiment of the disclosure, a second bank region BA2-2 may further include a fifth sub-region BSA5 in addition to the third sub-region BSA3 and the fourth sub-region BSA4. A third bank region BA3-2 may include a sixth sub-region BSA6 and a seventh sub-region BSA7.

The fifth sub-region BSA5 may be connected to the fourth sub-region BSA4 to have an integral shape. The second light control pattern CCP-G (see FIG. 4A) may overlap all of the third sub-region BSA3, the fourth sub-region BSA4, and the fifth sub-region BSA5. The fifth sub-region BSA5 may have a shape that protrudes from the third sub-region BSA3 in the first direction DR1. In an embodiment of the disclosure, the fifth sub-region BSA5 may have a shape that protrudes in the first direction DR1 from a portion of a long side of the third sub-region BSA3 having a rectangular shape.

The sixth sub-region BSA6 and the seventh sub-region BSA7 may be connected to each other to have an integral shape. The third light control pattern CCP-B (see FIG. 4A) may overlap both the sixth sub-region BSA6 and the seventh sub-region BSA7 in a plan view. The seventh sub-region BSA7 may have a shape that protrudes from the sixth sub-region BSA6 in a direction opposite to the first direction DR1. In an embodiment of the disclosure, the seventh sub-region BSA7 may have a shape that protrudes in a direction opposite to the first direction DR1 from a portion of a long side of the sixth sub-region BSA6 having a rectangular shape.

The second filter region FA2-2 may further include a fifth sub-filter region FA-P5 in addition to the third sub-filter region FA-P3 and the fourth sub-filter region FA-P4. The fifth sub-filter region FA-P5 may have a shape that protrudes in the first direction DR1 from a portion of a long side of the third sub-filter region FA-P3. At least a portion of the fifth sub-filter region FA-P5 may overlap the fifth sub-region BSA5 of the second bank region BA2-2 in a plan view.

The third filter region FA3-2 may include a sixth sub-filter region FA-P6 and a seventh sub-filter region FA-P7. The sixth sub-filter region FA-P6 may overlap the sixth sub-region BSA6 of the third bank region BA3-2 in a plan view. The sixth sub-filter region FA-P6 may have a rectangular shape with long sides extending in the second direction DR2 in a plan view. The seventh sub-filter region FA-P7 may have a shape that protrudes from a portion of a long side of the sixth sub-filter region FA-P6 in a direction opposite to the first direction DR1. At least a portion of the seventh sub-filter region FA-P7 may overlap the seventh sub-region BSA7 of the third bank region BA3-2 in a plan view.

Referring to FIG. 7C, in a display region DA-3 according to an embodiment of the disclosure, compared to the display region DA of FIG. 6A, the first bank region BA1-3 and the second bank region BA2-3 may not have a similar shape, and at least some of the widths and lengths of some sub-regions of the first bank region BA1-3 and the second bank region BA2-3 may be different from another one of the first bank region BA1-3 and the second bank region BA2-3. As illustrated in FIG. 7C, a second length L2-3 of the second sub-region BSA2-3 and a fourth length L4-3 of the fourth sub-region BSA4-3 may be different from each other in the second direction DR2. The second length L2-3 of the second sub-region BSA2-3 may be greater than the fourth length L4-3 of the fourth sub-region BSA4-3. In an embodiment, the first length L1 of the first sub-region BSA1-3 and the third length L3 of the third sub-region BSA3-3 may be substantially the same in the second direction DR2. Unlike what is illustrated, in another embodiment, the second length L2-3 of the second sub-region BSA2-3 may be less than the fourth length LA-3 of the fourth sub-region BSA4-3. In another embodiment, the second width W2 (see FIG. 6A) of the second sub-region BSA2-3 and the fourth width W4 (see FIG. 6A) of the fourth sub-region BSA4-3 may be different from each other.

In the display region DA-3 according to an embodiment of the disclosure, compared to the display region DA of FIG. 6A, the first filter region FA1-3 and the second filter region FA2-3 may not have a similar shape in a plan view, and at least some of the widths and lengths of some sub-filter regions of the first filter region FA1-3 and the second filter region FA2-3 may be different from the others. As illustrated in FIG. 7C, the length of the second sub-filter region FA-P23 and the length of the fourth sub-filter region FA-P43 may be different from each other in the second direction DR2. The length of the second sub-filter region FA-P23 may be greater than the length of the fourth sub-filter region FA-P43. In an embodiment, the length of the first sub-filter region FA-P13 and the length of the third sub-filter region FA-P33 may be substantially the same in the second direction DR2. Unlike what is illustrated, in another embodiment, the length of the second sub-filter region FA-P23 may be shorter than the length of the fourth sub-filter region FA-P43. In another embodiment, the width of the second sub-filter region FA-P23 and the width of the fourth sub-filter region FA-P43 may be different from each other.

Referring to FIG. 7D, in a display region DA-4 according to an embodiment of the disclosure, unlike the display region DA of FIG. 6A, each of a first bank region BA1-4 and a second bank region BA2-4 may not include a hypotenuse extending in the diagonal direction DR-S forming an acute angle with the first direction DR1. As illustrated in FIG. 7D, each of the second sub-region BSA2-4 and the fourth sub-region BSA4-4 may not include a hypotenuse and may have a rectangular shape including sides extending in each of the first direction DR1 and the second direction DR2 in a plan view. The shape of the first sub-region BSA1-4 in FIG. 7D and the shape of the first sub-region BSA1 in FIG. 6A may be substantially the same, and the shape of the third sub-region BSA3-4 in FIG. 7D and the shape of the third sub-region BSA3 in FIG. 6A may be substantially the same in a plan view.

In a display region DA-4 according to an embodiment of the disclosure, unlike the display region DA of FIG. 6A, each of the first filter region FA1-4 and the second filter region FA2-4 may not include a hypotenuse extending in the diagonal direction DR-S forming an acute angle with the first direction DR1. As illustrated in FIG. 7D, each of the second sub-filter region FA-P24 and the fourth sub-filter region FA-P44 may not include a hypotenuse and may have a rectangular shape including sides extending in each of the first direction DR1 and the second direction DR2 in a plan view. The shape of the first sub-filter region FA-P4 in FIG. 7D and the shape of the first sub-filter region FA-P1 in FIG. 6B may be substantially the same, and the shape of the third sub-filter region FA-P34 in FIG. 7D and the shape of the third sub-region FA-P3 in FIG. 6B may be substantially the same in a plan view.

Referring to FIG. 7E, in a display region DA-5 according to an embodiment of the disclosure, unlike the display region DA-4 of FIG. 7D, the lower or upper sides of the sub-regions included in each of the first bank region BA1-5 and the second bank region BA2-5 may not be aligned with each other. As illustrated in FIG. 7E, a second sub-region BSA2-5 may not protrude from the lower end of a long side of a first sub-region BSA1-5, but may protrude from the middle portion of a side of the first sub-region BSA1-5 in the first direction DR1. A fourth sub-region BSA4-5 may not protrude from the upper end of a long side of a third sub-region BSA3-5, but may protrude from the middle portion of a side of the third sub-region BSA3-5 in a direction opposite to the first direction DR1.

In the display region DA-5 according to an embodiment of the disclosure, unlike the display region DA-4 of FIG. 7D, the lower or upper sides of the sub-regions included in each of the first filter region FA1-5 and the second filter region FA2-5 may not be aligned with each other. As illustrated in FIG. 7E, a second sub-filter region FA-P25 may not protrude from the lower end of a long side of a first sub-filter region FA-P15, but may protrude from the middle portion of a side of the first sub-filter region FA-P15 in the first direction DR1. A fourth sub-filter region FA-P45 may not protrude from the upper end of a long side of a third sub-filter region FA-P35, but may protrude from the middle portion of a side of the third sub-filter region FA-P35 in a direction opposite to the first direction DR1.

Hereinafter, a method of manufacturing a display panel according to an embodiment of the disclosure will be described.

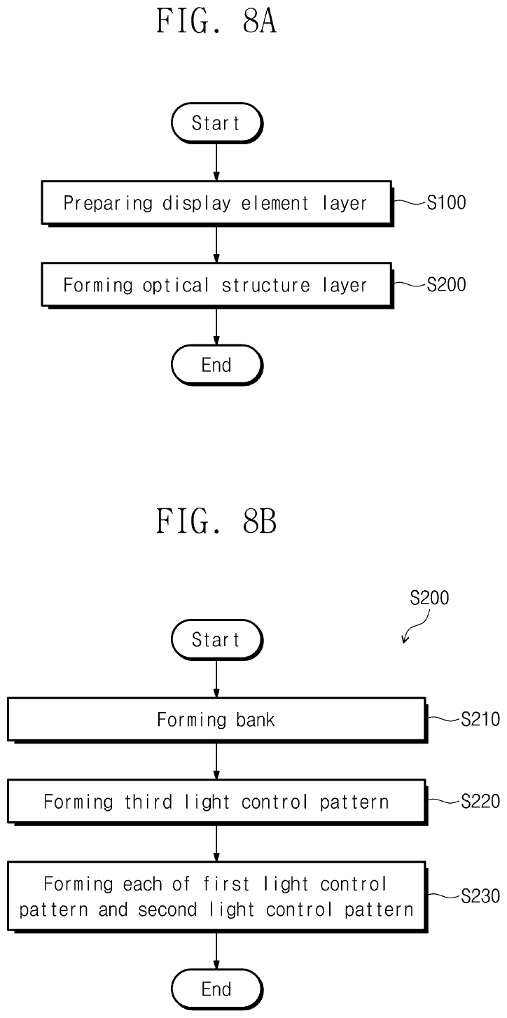

FIG. 8A is a flowchart of a method of manufacturing a display panel according to an embodiment of the disclosure. FIG. 8B is a flow chart of some steps in the method of manufacturing the display panel according to an embodiment of the disclosure. FIG. 8B is a flow chart of forming an optical structure layer (S200) in the method of manufacturing the display panel according to an embodiment of the disclosure.

Referring to FIGS. 8A and 8B, a method of manufacturing the display panel according to an embodiment of the disclosure may include preparing a display element layer including a light-emitting element that outputs source light (S100), and forming an optical structure layer on the light-emitting element (S200). The forming of the optical structure layer (S200) may include forming a bank, in which first to third bank openings are formed, on the light-emitting element (S210), patterning a photoresist material in the third bank opening to form a third light control pattern (S220), and respectively forming a first light control pattern and a second light control pattern in the first bank opening and the second bank opening through an inkjet process (S230). The descriptions of the first bank opening, the second bank opening, the third bank opening, and the bank regions defined by the first bank opening, the second bank opening, the third bank opening, which are given above with reference to FIGS. 1B to 7E, may be equally applied to the descriptions of the same, which are given here and hereafter.

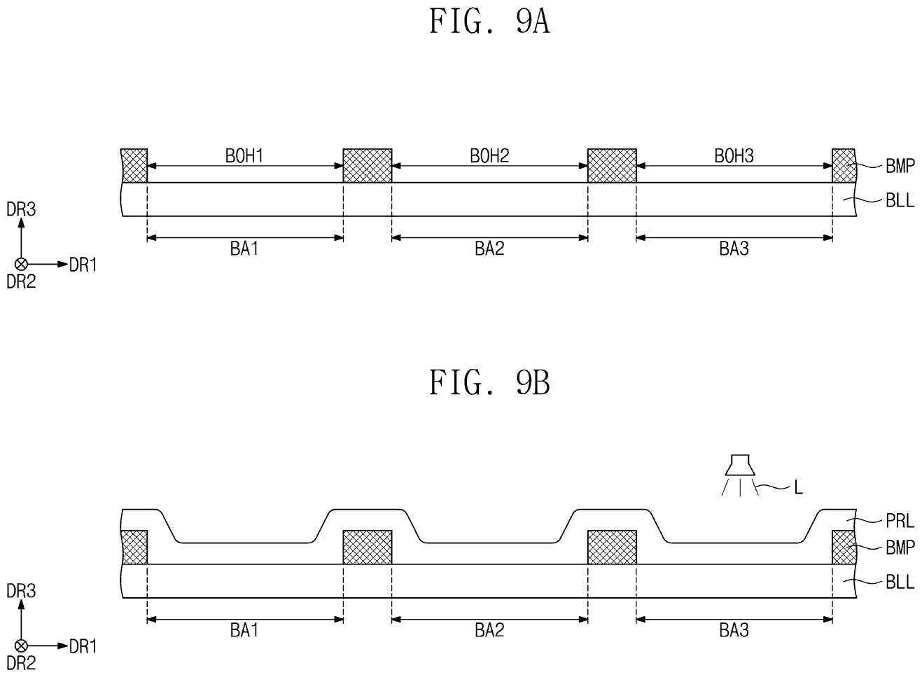

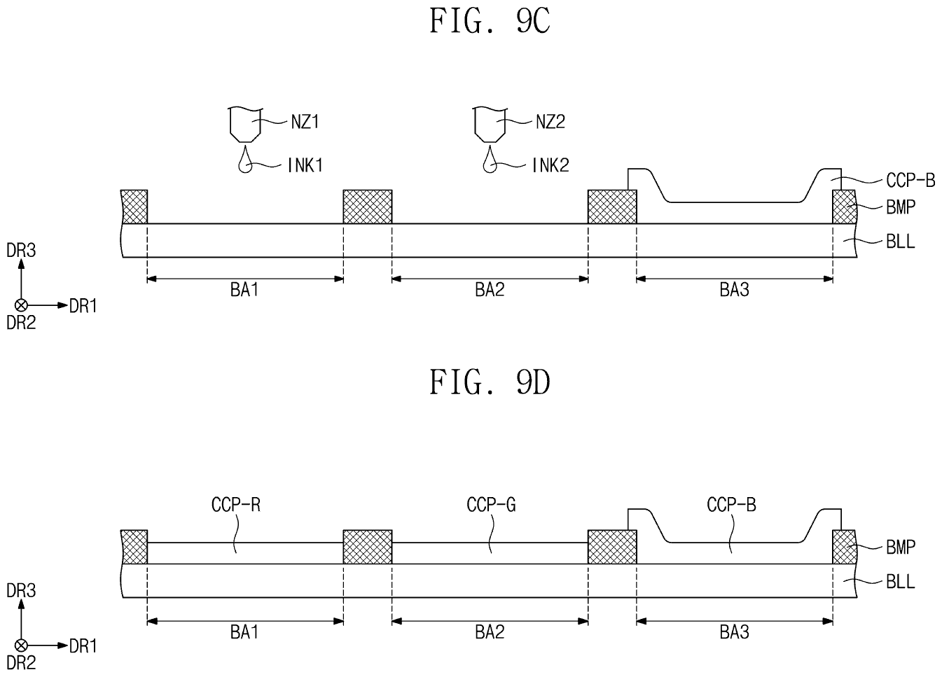

FIGS. 9A to 9D are schematic cross-sectional views illustrating some steps in the method of manufacturing the display panel according to an embodiment of the disclosure. FIGS. 9A to 9D schematically illustrate some steps of forming an optical structure layer in the method of manufacturing the display panel according to an embodiment of the disclosure.

Referring to FIG. 9A, the method of manufacturing the display panel according to an embodiment of the disclosure may include forming a bank BMP including a first bank opening BOH1, a second bank opening BOH2, and a third bank opening BOH3. The bank BMP may be formed on a base member BLL. The base member BLL may provide a base surface on which the bank BMP and light control patterns CCP-R, CCP-G, and CCP-B (see FIG. 9D) are formed. For example, in case that the display panel DP illustrated in FIG. 4A is manufactured, the base member BLL may be a second barrier layer CAP2, and in case that the display panel DP-1 illustrated in FIG. 4B is manufactured, the base member BLL may be a first barrier layer CAP1.

Referring to FIGS. 9B and 9C, the method of manufacturing the display panel according to an embodiment of the disclosure may include applying a photoresist material PRL inside at least the third bank opening BOH3 and patterning to form a third light control pattern CCP-B. As illustrated in FIG. 9B, the photoresist material PRL may be provided not only inside the third bank opening BOH3 but also inside the first bank opening BOH1 and the second bank opening BOH2, and may be provided to the upper portion of the bank BMP. For example, the photoresist material PRL may be provided entirely on the upper portion of the base member BLL, and after an exposure process to provide light L, an uncured portion may be removed to form the third light control pattern CCP-B. In the patterning of the photoresist material PRL, a separate photomask may be provided to perform an exposure process on only a portion of the photoresist material PRL. FIG. 9B schematically illustrates a negative photoresist that is cured by irradiating light L on the photoresist material PRL corresponding to the third bank opening BOH3 according to an embodiment, but the disclosure is not limited thereto, and in another embodiment, the photoresist material PRL may be a positive photoresist, and light may be irradiated onto a portion of the photoresist material PRL except for the third bank opening BOH3.

Referring to FIGS. 9C and 9D, the method of manufacturing the display panel according to an embodiment of the disclosure may include forming the first light control pattern CCP-R and the second light control pattern CCP-G in each of the first bank opening BOH1 and the second bank opening BOH2 through an inkjet process. The first light control pattern CCP-R may be formed by providing a first ink INK1 inside the first bank opening BOH1 through a first nozzle NZ1. The second light control pattern CCP-G may be formed by providing a second ink INK2 inside the second bank opening BOH2 through a second nozzle NZ2. The first ink INK1 and the second ink INK2 respectively forming the first light control pattern CCP-R and the second light control pattern CCP-G may include quantum dots.

In an embodiment, an inkjet impact point on which the first ink INK1 is impacted through the first nozzle NZ1 may be the second sub-region BSA2 described above in FIG. 6A and the like and a portion of the first sub-region BSA1 parallel to the second sub-region BSA2 in the first direction DR1. An inkjet impact point on which the second ink INK2 is impacted through the second nozzle NZ2 may be the fourth sub-region BSA4 described above in FIG. 6A and the like and a portion of the third sub-region BSA3 parallel to the fourth sub-region BSA4 in the first direction DR1. In the method of manufacturing the display panel according to an embodiment of the disclosure, since the inkjet processes of the first ink INK1 and the second ink INK2 are respectively performed through portions having a wide width in the first bank region BA1 and the second bank region BA2, the process efficiency of forming the first light control pattern CCP-R and the second light control pattern CCP-G may be improved.

According to an embodiment of the disclosure, as some of the bank opening regions provided in the light control layer include multiple sub-regions having a small width, it may be possible to implement high resolution, and as some of the bank opening regions are formed to have a large width for an inkjet process, it may be possible to secure an inkjet process impact region, thus being able to improve the process efficiency of the process of manufacturing the display panel. As it is possible to prevent a color fringing phenomenon in which the colors of other pixels are provided in the form of an outline at the edge portions of some pixels, the display quality of the display panel may be improved.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display panel comprising:
a display element layer including a light-emitting element that outputs a source light; and
an optical structure layer that is disposed on the light-emitting element and transmits the source light or converts the source light into light of a different wavelength, wherein
the optical structure layer comprises:
a light control layer disposed on the light-emitting element and comprising:
a bank having a first bank opening, a second bank opening, and a third bank opening sequentially disposed in a first direction;
a first light control pattern disposed in the first bank opening;
a second light control pattern disposed in the second bank opening; and
a third light control pattern disposed in the third bank opening,
a first bank region defined by the first bank opening comprises:
a first sub-region extending in a second direction intersecting the first direction; and
a second sub-region protruding from the first sub-region in the first direction,
a second bank region defined by the second bank opening comprises:
a third sub-region extending in the second direction; and
a fourth sub-region protruding from the third sub-region in a direction opposite to the first direction to the first bank region,
a third bank region is defined by the third bank opening,
center lines of the second sub-region and the fourth sub-region in the second direction do not overlap each other in the first direction; and
center lines of the first sub-region, the third sub-region, and the third bank region in the second direction are aligned with each other.

2. The display panel of claim 1, wherein each of the second sub-region and the fourth sub-region includes a hypotenuse extending in a diagonal direction forming an acute angle with the first direction.

3. The display panel of claim 1, wherein a length of the third bank region in the second direction is less than a length of each of the first bank region and the second bank region in the second direction.

4. The display panel of claim 1, wherein
the first sub-region comprises a first side and a second side each extending in the first direction and spaced apart from each other in the second direction,
the third sub-region comprises a third side and a fourth side each extending in the first direction and spaced apart from each other in the second direction,
the first side and the third side are aligned with each other in the first direction, and
the second side and the fourth side are aligned with each other in the first direction.

5. The display panel of claim 4, wherein
the second sub-region comprises a fifth side aligned with the second side in the first direction, and
the fourth sub-region comprises a sixth side aligned with the third side in the first direction.

6. The display panel of claim 1, wherein
the optical structure layer further comprises a color filter layer disposed on the light control layer, and
the color filter layer comprises:
a first color filter overlapping the first bank region in a plan view;
a second color filter overlapping the second bank region in a plan view; and
a third color filter overlapping the third bank region in a plan view.

7. The display panel of claim 6, wherein
the first color filter is disposed in a first filter region that emits light of a first wavelength,
the second color filter is disposed in a second filter region that emits light of a second wavelength,
the third color filter is disposed in a third filter region that emits light of a third wavelength, and
the third wavelength is shorter than the first wavelength and the second wavelength.

8. The display panel of claim 7, wherein the third filter region has a rectangular shape in a plan view.

9. The display panel of claim 7, wherein
the first filter region comprises:
a first sub-filter region overlapping the first sub-region in a plan view; and
a second sub-filter region protruding from the first sub-filter region in the first direction and at least partially overlapping the second sub-region in a plan view, and
the second filter region comprises:
a third sub-filter region overlapping the third sub-region in a plan view; and
a fourth sub-filter region protruding from the third sub-filter region in a direction opposite to the first direction and at least partially overlapping the fourth sub-region in a plan view.

10. The display panel of claim 9, wherein a minimum distance from an end of the first sub-region to an end of the first filter region and a minimum distance from an end of the second sub-region to an end of the second filter region are substantially equal.

11. The display panel of claim 1, wherein
the second bank region further comprises a fifth sub-region protruding from the third sub-region in the first direction to the third bank region, and
the third bank region comprises:
a sixth sub-region extending in the second direction; and
a seventh sub-region protruding from the sixth sub-region in a direction opposite to the first direction to the second bank region.

12. The display panel of claim 1, wherein a length of the second sub-region and a length of the fourth sub-region in the second direction are substantially same.

13. The display panel of claim 1, wherein a length of the second sub-region and a length of the fourth sub-region are different from each other in the second direction.

14. The display panel of claim 1, wherein the third bank region has a rectangular shape in a plan view.

15. The display panel of claim 1, wherein the third light control pattern comprises a photosensitive resin.

16. The display panel of claim 1, wherein a width of the first sub-region and a width of the third sub-region in the first direction are substantially same.

17. The display panel of claim 1, wherein a separation distance from the second sub-region to the third sub-region and a separation distance from the third sub-region to the third bank region in the first direction are substantially same.

18. A display panel comprising:
a display element layer including a light-emitting element that outputs a source light; and
an optical structure layer that is disposed on the light-emitting element and transmits the source light or converts the source light into light of a different wavelength, wherein
the optical structure layer comprises:
a light control layer disposed on the light-emitting element and comprising:
a bank having a first bank opening, a second bank opening, and a third bank opening sequentially disposed in a first direction;
a first light control pattern disposed in the first bank opening;
a second light control pattern disposed in the second bank opening; and
a third light control pattern disposed in the third bank opening,
a first bank region defined by the first bank opening comprises:
a first sub-region; and
a second sub-region protruding from the first sub-region in the first direction,
a second bank region defined by the second bank opening comprises:
a third sub-region; and
a fourth sub-region protruding from the third sub-region in a direction opposite to the first direction to the first bank region,
a third bank region is defined by the third bank opening,
each of the second sub-region and the fourth sub-region protrudes in a staggered form from an upper portion or a lower portion of a side of each of the first sub-region and the third sub-region, and
center lines of the first sub-region, the third sub-region, and the third bank region in a second direction intersecting the first direction are aligned with each other.

19. An electronic device comprising:
a display panel providing an image; and
a power module disposed below the display panel and supplying power,
wherein the display panel comprises:
a display element layer including a light-emitting element that outputs a source light; and
an optical structure layer that is disposed on the light-emitting element and transmits the source light or converts the source light into light of a different wavelength, wherein
the optical structure layer comprises:
a light control layer disposed on the light-emitting element and comprising:
a bank having a first bank opening, a second bank opening, and a third bank opening sequentially disposed in a first direction;
a first light control pattern disposed in the first bank opening;
a second light control pattern disposed in the second bank opening; and
a third light control pattern disposed in the third bank opening,
a first bank region defined by the first bank opening comprises:
a first sub-region extending in a second direction intersecting the first direction; and
a second sub-region protruding from the first sub-region in the first direction,
a second bank region defined by the second bank opening comprises:
a third sub-region extending in the second direction; and
a fourth sub-region protruding from the third sub-region in a direction opposite to the first direction to the first bank region,
a third bank region is defined by the third bank opening,
center lines of the second sub-region and the fourth sub-region in the second direction do not overlap each other in the first direction; and
center lines of the first sub-region, the third sub-region, and the third bank region in the second direction are aligned with each other.

20. The electronic device of claim 19, wherein each of the second sub-region and the fourth sub-region comprises a hypotenuse extending in a diagonal direction which is a direction between the first direction and the second direction.
